(19) United States
(12) Patent Application Publication
(10) Pub. No.: US 2009/0291557 A1
(43) Pub. Date: Nov. 26, 2009

(54) MICROREACTOR FOR SOLUTION DEPOSITION AND METHOD OF USE

(75) Inventors: KEVIN MCPEAK, PHILADELPHIA, PA (US); JASON B. BAXTER, HAVERTOWN, PA (US)

Correspondence Address: KNOBLE, YOSHIDA & DUNLEAVY, EIGHT PENN CENTER, SUITE 1350, 1628 JOHN F KENNEDY BLVD, PHILADELPHIA, PA, 19103, US

(73) Assignee: DREXEL UNIVERSITY, PHILADELPHIA, PA (US)

(21) Appl. No.: 12/469,645

(22) Filed: May 20, 2009

Related U.S. Application Data
(60) Provisional application No. 61/054,911, filed on May 21, 2008.

(51) Int. Cl. H01L 21/285; C23C 16/52; C23C 16/50

(52) U.S. Cl. 438/680; 118/712; 118/723 R; 257/E21.17

(57) ABSTRACT

A novel microreactor producing customized deposition products and a method for optimizing the deposition process. The microreactor has a unique design with high surface-to-volume ratio that produces high deposition yield with a minimal amount of waste. The invention may be particularly applicable to the field of optoelectronics and photovoltaics.

### CROSS-REFERENCE TO RELATED APPLICATIONS

This application claims priority to and is a non-provisional of U.S. Provisional Patent Application No. 61/054,911, filed on May 21, 2008, pursuant 35 U.S.C. 119(e), the entire disclosure of which is incorporated herein by reference.

### BACKGROUND OF THE INVENTION

1. Field of Invention

The present invention is directed to a novel microreactor and a method of chemical deposition. It is envisioned that the invention may be particularly relevant to fabricating semiconductors and nanomaterials for use in the fields of optoelectronics and photovoltaics as well as for high throughput screening methods.

2. Brief Description of the Prior Art

Chemical bath deposition (CBD) is a simple and inexpensive method for depositing thin films of many different semiconductors. CBD merely requires a vessel to contain an aqueous solution, standard precursors such as metal salts, complexing agents, and pH buffers, a substrate on which to deposit deposition products, and a means for heating the vessel. CBD is widely used for deposition of II-VI semiconductors, such as CdS, CdSe, and ZnS, IV-VI semiconductors, such as PbS and PbSe, oxides, such as ZnO, In₂O₃, SnO₂, and ternary compounds, such as Zn₁₋ₓCdₓO and CuInSe₂ (Hodes, G., Chemical Solution Deposition of Semiconductor Films (Marcel Dekker, Inc., New York, 2003 It is also increasingly used in commercial processes, such as CdS buffer layer deposition for thin film photovoltaics.

Further work, however, is required to control the mechanisms for CBD deposition growth and customize the properties of CBD deposits. The four common mechanisms in CBD are the simple ion-by-ion, simple cluster (hydroxide), complex decomposition ion-by-ion, and complex decomposition cluster mechanisms (Hodes, G., Chemical Solution Deposition of Semiconductor Films (Marcel Dekker, Inc., New York, 2003)). The first two involve free cations and anions while the latter two rely on forming and breaking metal or anion complexes. In the ion-by-ion mechanisms, individual ions impinge upon and attach to a nucleus, resulting in crystal growth. In the cluster mechanisms, colloidal clusters, usually hydroxides, form and attach to the substrate followed by exchange of the hydroxide with another anion. The mechanism and kinetics of deposition depend strongly on the bath conditions, particularly temperature, pH, and reactant and complexing agent concentrations (Hodes, G., Chemical Solution Deposition of Semiconductor Films (Marcel Dekker, Inc., New York, 2003)). Lack of understanding of the CBD growth process has led to criticism for being too recipe-specific and not easily generalized to other conditions or other systems.

Another drawback is that CBD often has very inefficient utilization of reactants and significant waste solvent generation (Hodes, G., Chemical Solution Deposition of Semiconductor Films (Marcel Dekker, Inc., New York, 2003); Boyle, D. S., Bayer, A., Heinrich, M. R., Robbe, O., and O'Brien, P., “Novel approach to the chemical bath deposition of chalcogenide semiconductors”, Thin Solid Films 361, 150 (2000); Nair, P. K., Garcia, V. M., Gomez-Daza, O., and Nair, M. T. S., “High thin-film yield achieved at small substrate separation in chemical bath deposition of semiconductor thin films”, Semiconductor Science and Technology 16, 855 (2001); Readigos, A. A. C., Garcia, V. M., Gomezdaza, O., Campos, J., Nair, M. T. S., and Nair, P. K., “Substrate spacing and thin-film yield in chemical bath deposition of semiconductor thin films”, Semiconductor Science and Technology 15, 1022 (2000)). For example, in CdS deposition, typically only about 2% of the cadmium feedstock is usefully deposited. This results in the generation of significant volumes of cadmium-contaminated water, as well as generation of cadmium-containing precipitates.

Also, in a typical CBD process, the entire bath is heated, and thus deposition on the substrate is limited by competing precipitation in solution and deposition on the reaction vessel walls. A large volume of the solvent then supports reactants that do not contribute toward desirable deposition. Additional care must be taken to ensure that the solution is well mixed and uniformly heated, which can contribute to additional non-uniformity of deposition across the substrate area if neglected. Therefore, careful design of the reactor geometry is critical to efficient utilization of reactants, minimization of waste solvent, and uniformity of deposition.

Much effort has been devoted to developing recipes for production of high quality films, but efficient conversion of initial metal-containing reactants to a film deposited on the substrate, which hence will be called yield, has been largely ignored. Low yield is of concern in all industrial processes and is particularly worrisome for toxic materials, such as Cd. For example, yield of CdS is often as low as 2-10% (Boyle, D. S., Bayer, A., Heinrich, M. R., Robbe, O., and O'Brien, P., “Novel approach to the chemical bath deposition of chalcogenide semiconductors”, Thin Solid Films 361, 150 (2000); Readigos, A. A. C., Garcia, V. M., Gomezdaza, O., Campos, J., Nair, M. T. S., and Nair, P. K., “Substrate spacing and thin-film yield in chemical bath deposition of semiconductor thin films”, Semiconductor Science and Technology 15, 1022 (2000)) and the yield of ZnO is often about 3%.

In response to these concerns, three methods that have been proposed to improve yield. First Boyle D. S., Bayer, A., Heinrich, M. R., Robbe, O., and O'Brien, P., “Novel approach to the chemical bath deposition of chalcogenide semiconductors,” Thin Solid Films 361-362, 150 (2000), describes a recycle system to recover Cd using a series of filters and water treatment stages. This solution, however, is expensive, cumbersome and does not address the issue of low yield in the initial pass through the reactor. Boyle et al. also suggests heating only the substrate, rather than the entire deposition bath. Depending on the geometry, this method can eliminate deposition on the cooler reactor walls and reduces precipitation away from the substrate.

Nair, P. K., Garcia, V. M., Gomez-Daza, O., and Nair, M. T. S., “High thin-film yield achieved at small substrate separation in chemical bath deposition of semiconductor thin films”, Semiconductor Science and Technology 16, 855 (2001) offers a method to increase yield by reducing reactor volume, and thereby reducing undesired precipitation. Using a variable length rectangular reactor with substrates forming the two ends of the reactor, Nair increased yield from 5-10% to 40-50% by decreasing the distance between the substrates from 10 mm to 1 mm. A larger fraction of reactants diffused to the substrate and deposited rather than precipitating in the bulk solution. Additionally, there is less reactor wall area available for deposition using this design. The shortcoming of this idea, as implemented by Nair et al. in a batch process, is that reduced substrate separation also reduces terminal film thickness because of the lower initial charge of reactants in the lower volume bath that results when the distance between the substrates is reduced to 1 mm. Film thickness made by the process of Nair et al. increases with increasing substrate spacing due to the provision of a greater initial number of moles of reactants in a larger volume bath until a point where saturation occurs due to mass transport limitations. This saturation point is in the range of the spacing of 1-10 mm depending on reaction conditions. The product of terminal thickness multiplied by the yield reaches a maximum at substrate spacing of less than 2 mm for all conditions reported (Readigos, A. A. C., Garcia, V. M., Gomezdaza, O., Campos, J., Nair, M. T. S., and Nair, P. K., “Substrate spacing and thin-film yield in chemical bath deposition of semiconductor thin films”, Semiconductor Science and Technology 15, 1022 (2000)). CBD, however, has yet to be efficiently and effectively applied to depositions using sub-millimeter reaction channels. Although microreactors for making liquid and gas products (Kiwi-Minsker, L. and Renken, A., “Microstructured reactors for catalytic reactions”, Catalysis Today 110, 2 (2005)) and devices with sub-millimeter channels for fluid flow that can be used for chemical production and analysis (Jensen, K. F., “Microreaction engineering—is small better?” Chemical Engineering Science 56, 293 (2001); Kiwi-Minsker, L. and Renken, A., “Microstructured reactors for catalytic reactions”, Catalysis Today 110, 2 (2005); Ehrfeld, W., Golbig, K., Hessel, V., Lowe, H., and Richter, T., “Characterization of mixing in micromixers by a test reaction: Single mixing units and mixer arrays”, Industrial & Engineering Chemistry Research 38, 1075 (1999); van den Berg, A., Olthuis, W., and Bergveld, P., Micro total analysis systems (Kluwer Academic, Dordrecht, 2000); Walter, S., Malmberg, S., Schmidt, B., and Liauw, M. A., “Mass transfer limitations in microchannel reactors”, Catalysis Today 110, 15 (2005); Lowe, H. and Ehrfeld, W., “State-of-the-art in microreaction technology: concepts, manufacturing and applications”, Electrochimica Acta 44, 3679 (1999)) are known in the art, such as that described in U.S. Patent Application Publication No. 2007/0020400, these devices require complex processing involving catalysts on the reactor walls to convert precursors in the fluid and gas or liquid product is removed in the flowing stream No solids are deposited at any point.

In general, microreactors are advantageous compared to larger scale CBD reactors since their higher surface to volume ratio and laminar flow enables precise knowledge of the heat, mass, and momentum transport in the system and control of over process variables, such as the temperature profile. As a result, microreactors can provide for more aggressive reaction conditions and promote faster process characterization and development. Such advantages would therefore be valuable for use in determining the optimal deposition process for semiconductors and nanomaterials having enhanced material and physical characteristics. Therefore, there is a need to develop microreactors capable of effectively and efficiently optimizing the chemical deposition process.

### SUMMARY OF THE INVENTION

The invention is directed to novel embodiments of a microreactor and methods for use thereof. In one aspect, the microreactor includes a base comprising a channel formed therein, a substrate forming a structural portion of the microreactor, and a heating element operatively associated with and capable of transferring heat to the substrate, wherein the microreactor is designed to have a surface-to-volume ratio about 0.5 to about 5.0 mm⁻¹.

The invention is also directed to a method for using a microreactor including the steps of providing a microreactor, introducing a chemical to the microreactor, recirculating said chemical through a flow channel of the microreactor and said channel, controlling an environmental condition of the microreactor, depositing said chemical on the substrate, forming a deposition product and removing the substrate and deposition product.

The microreactor of the present invention is advantageous because it produces high deposition yields, minimizes waste generated by the deposition process, and may be used to fabricate deposition products having custom designed morphology and properties since it permits relatively precise temperature control in the reactor.

### BRIEF DESCRIPTION OF THE DRAWINGS

FIG. 1 is a cross-sectional view of one embodiment of a microreactor, wherein the substrate is shown to be removably fastened to the base.

FIG. 2 is a cross-sectional view the microreactor of FIG. 1, wherein the cap, substrate and base are securely fastened.

FIG. 3 is a cross-sectional view of another embodiment of the microreactor including a pair of openings and plugs.

FIG. 4 is a side view of the microreactor of FIG. 3.

FIG. 5 is a top view of the microreactor of FIG. 3.

FIG. 6 is a perspective view of the microreactor of FIG. 3.

FIG. 7 is a cross-sectional view of a continuous flow microreactor shown configured for growing nanowires, including a laminar flow profile, a temperature gradient and reactant depletion along the length of the channel.

FIG. 8(a) is a perspective view of a microreactor having a plurality of channels that may be adapted for batch or continuous flow operation.

FIG. 8(b) is a cross-section of a microreactor having a plurality of channels adapted for batch or continuous flow operation.

FIG. 9 is a cross-sectional view of an embodiment of an electrodeposition reactor in accordance with the present invention

FIG. 10(a) is a side view of a doped nanowire having a conductive core and insulating shell.

FIG. 10(b) is a side view of a doped nanowire having a band gap engineered core shell.

FIG. 10(c) is a side view of a doped nanowire having an axially graded band gap.

FIG. 11 is a graph of nanowire length as a function of growth time for nanowires grown in a batch microreactor.

FIG. 12 is a graph of nanowire dimension versus time showing induction, growth and terminal phases for nanowires grown in a conventional CBD reactor.

FIG. 13(a) is a cross-sectional SEM image of ZnO nanowires that were grown in the microreactor for 15 minutes.

FIG. 13(b) is a cross-sectional SEM image of ZnO nanowires that were grown in the microreactor for 2 hours.

FIG. 13(c) is a cross-sectional SEM image of ZnO nanowires that were grown in the microreactor for 4 hours.

FIG. 13(d) is a cross-sectional SEM image of ZnO nanowires that were grown in the vial reactor for 30 minutes.

FIG. 13(e) is a cross-sectional SEM image of ZnO nanowires that were grown in the vial reactor for 2 hours.

FIG. 13(f) is a cross-sectional SEM image of ZnO nanowires that were grown in the vial reactor for 4 hours.

FIG. 14(a) is a top view SEM image of ZnO nanowires that were grown in the microreactor for 2 hours.

FIG. 14(b) is a cross-sectional SEM image of the ZnO nanowires of FIG. 14(a).

FIG. 14(c) is a top view SEM image of ZnO nanowires that were grown in the vial reactor for 2 hours.

FIG. 14(d) is a cross-sectional SEM image of the ZnO nanowires of FIG. 14(c).

FIG. 15(a) is a graph of the amount of ZnO deposited on a substrate as a function of time for a batch microreactor and a CBD vial reactor. The inset figure is a magnification of the first 35 minutes of growth.

FIG. 15(b) is a graph of ZnO deposition rate as a function of time for a batch microreactor and CBD vial reactor.

FIG. 15(c) is a graph of the concentration of Zn²⁺_{(aq)} in the bath solution as a function of time for a batch microreactor and a vial reactor.

FIG. 16 is a graph of ZnO deposition yield as a function of time for a batch microreactor at a heating rate of 34° C./min and a CBD vial reactor.

FIG. 17 is an X-ray diffraction 2θ scan of a ZnO seed film and nanowires grown in a batch microreactor and vial reactor for 3 hours. The vertical bars represent the intensities for a wurtzite ZnO reference powder.

FIG. 18 is a Raman spectra of ZnO nanowires grown in a batch microreactor and CBD vial reactor.

FIG. 19(a) is a SEM image of ZnO nanowires grown at the inlet of a microreactor after 4 hours at a flow rate of 0.72 mL/hr and an initial concentration of 0.025M.

FIG. 19(b) is a SEM image of ZnO nanowires grown 6 mm downstream from the inlet of a microreactor after 4 hours at a flow rate of 0.72 mL/hr and an initial concentration of 0.025M.

FIG. 19(c) is a SEM image of ZnO nanowires grown 12 mm downstream from the inlet of a microreactor after 4 hours at a flow rate of 0.72 mL/hr and an initial concentration of 0.025M.

FIG. 19(d) is a SEM image of ZnO nanowires grown 18 mm downstream from the inlet of a microreactor after 4 hours at a flow rate of 0.72 mL/hr and an initial concentration of 0.025M.

FIG. 19(e) is a SEM image of ZnO nanowires grown at the inlet of a microreactor after 4 hours at a flow rate of 2.88 mL/hr and an initial concentration of 0.025M.

FIG. 19(f) is a SEM image of ZnO nanowires grown 6 mm downstream from the inlet of a microreactor after 4 hours at a flow rate of 2.88 mL/hr and an initial concentration of 0.025M.

FIG. 19(g) is a SEM image of ZnO nanowires grown 12 mm downstream from the inlet of a microreactor after 4 hours at a flow rate of 2.88 mL/hr and an initial concentration of 0.025M.

FIG. 19(h) is a SEM image of ZnO nanowires grown 18 mm downstream from the inlet of a microreactor after 4 hours at a flow rate of 2.88 mL/hr and an initial concentration of 0.025M.

FIG. 20 is a graph of nanowire length as a function of downstream position for 0.72 mL/hr and 2.88 mL/hr flow rates. The inset figure is a graph of normalized nanowire length as a function of downstream nanowire position.

FIG. 21 is an X-ray diffraction 2θ scan of a ZnO seed film and nanowires grown in a continuous flow microreactor for 4 h at various flow rates. The vertical bars represent the intensities for a wurtzite ZnO reference powder.

FIG. 22(a) is a graph of PL measurements of nanowires grown at 0.72 mL/hr at different downstream positions.

FIG. 22(b) is a graph of normalized PL intensity as a function of energy of the nanowires grown at different downstream positions from the inlet of the microreactor channel, before and after annealing.

FIG. 22(c) is a graph of band gap as a function of position from inlet for nanowires grown at 0.72 and 2.88 mL/hr flow rates and annealed nanowires grown at 0.72 mL/hr.

### DETAILED DESCRIPTION OF THE PREFERRED EMBODIMENTS

For illustrative purposes, the principles of the present invention are described by referencing various exemplary embodiments thereof. Although certain embodiments of the invention are specifically described herein, one of ordinary skill in the art will readily recognize that the same principles are equally applicable to, and can be employed in, other apparatuses and methods. Before explaining the disclosed embodiments of the present invention in detail, it is to be understood that the invention is not limited in its application to the details of any particular embodiment shown. The terminology used herein is for the purpose of description and not of limitation. Further, although certain methods are described with reference to certain steps that are presented herein in certain order, in many instances, these steps may be performed in any order as may be appreciated by one skilled in the art, and the methods are not limited to the particular arrangement of steps disclosed herein.

For purposes of the present invention, “channel” may refer to a chamber, well or a container of any depth, width, height, shape or configuration.

As used herein, “microreactor” refers to a small reactor typically having a channel depth of not more than about 5 mm.

As used herein, “chemical deposition” may refer to chemical bath deposition, electrodeposition hydrothermal deposition, or a combination thereof.

As used herein, “chemical reactant” may include any chemical designed to interact with a substrate. In an exemplary embodiment, the chemical reactant is dissolved in a precursor solution and may interact with, and form a deposit, on the substrate.

As used herein, “deposition” may refer to chemical deposition, including chemical bath deposition, electrodeposition, hydrothermal deposition or a combination thereof.

As used herein, “deposition yield” refers to the fraction of chemical reactant that reacts with the substrate. Yield, Y, is calculated by equation 1, below:

$$Y = \frac{LA ϕρ}{{C}_{O} VM} , \qquad ( Equation 1 )$$

where L is the average nanowire length, A is the growth area of the substrate, φ is the solid volume fraction of the nanowire array, ρ is the density of the deposition material, C₀ is the initial concentration of cation in solution, V is the volume of the bath, and M is the molecular weight of the deposition material. In the case of a non-porous film, L is film thickness and φ is 1.

As used herein, “percentage deposition yield” is measured in terms of the amount of chemical reactant introduced to the microreactor system that reacts with the substrate.

Additionally, as used herein, “surface-to-volume ratio” may refer to a ratio of the area of the substrate surface S_{sub} to either the volume of chemical reactant in the microreactor or the volume capacity of the microreactor (V).

It must be noted that as used herein and in the appended claims, the singular forms “a”, “an”, and “the” include plural references unless the context clearly dictates otherwise. Thus, for example, reference to “a channel” includes a plurality of channels and equivalents thereof known to those skilled in the art, and so forth. As well, the terms “a” (or “an”), “one or more” and “at least one” can be used interchangeably herein. It is also to be noted that the terms “comprising”, “including”, and “having” can be used interchangeably.

The present invention is directed to a microreactor and a method for use thereof. The microreactor of the invention may be used to fabricate products by chemical deposition which may optionally be designed to have customized morphology and/or properties. The microreactor of the present invention enables high yield chemical deposition that substantially reduces the volume of waste generated by the reaction relative to conventional CBD processes designed to provide similar deposits. The microreactor of the present invention is also particularly suitable for use in high throughput screening methods and/or for fabrication of library materials to be used in high throughput screening devices such as two-dimensional combinatorial arrays.

The microreactor of the present invention may enable deposition of a wide variety of materials including, but not limited to, thin films, coatings and nanowire arrays, and is preferably used for deposition of oxides, chalcogenides and thin metal films. In an exemplary embodiment, the microreactor may be used to deposit thin films and/or nanowires of single materials or composite materials consisting of chalcogenides, preferably II-VI chalcogenides, and oxides of interest in optoelectronic applications. These materials may include but are not limited to binaries such as CdS, CdSe, CdO, CdTe, ZnO, ZnSe, ZnS, ternaries such as (Zn,Cd)O, Cd(S,Se), CuInSe₂ (CIS) and metals such as Fe, Ni and Co.

The microreactor of the present invention improves upon CBD processes by the provision of a relatively high ratio of the substrate surface area (S_{sub}) to reactant and/or reactor volume (V). It has been found that design of the reactor to maximize S_{sub}/V and make S_{sub} as close to the reactor surface area (S_{reactor}) as possible, can lead to significantly improved yields relative to conventional batch CBD processes. However, the maximum of S_{sub}/V is limited by factors such as pressure drop in the reactor, deposition film thickness and the potential for reactor clogging due to deposition. In addition, optimal results can be obtained using a channel thickness of 0.1-5 mm in order to ensure that the maximum distance from the reactant when in the reactor to the substrate is 0.1-5 mm for reactors having a single substrate surface, or, 0.05-2.5 mm for reactors employing opposite substrate surfaces. Optimal surface-to-volume ratios (S_{sub}/V) are from about 0.1 to about 10 mm⁻¹, more preferably, are about 0.2 to about 5 mm⁻¹, and, most preferably, are about 0.7 to about 1.5 mm⁻¹.

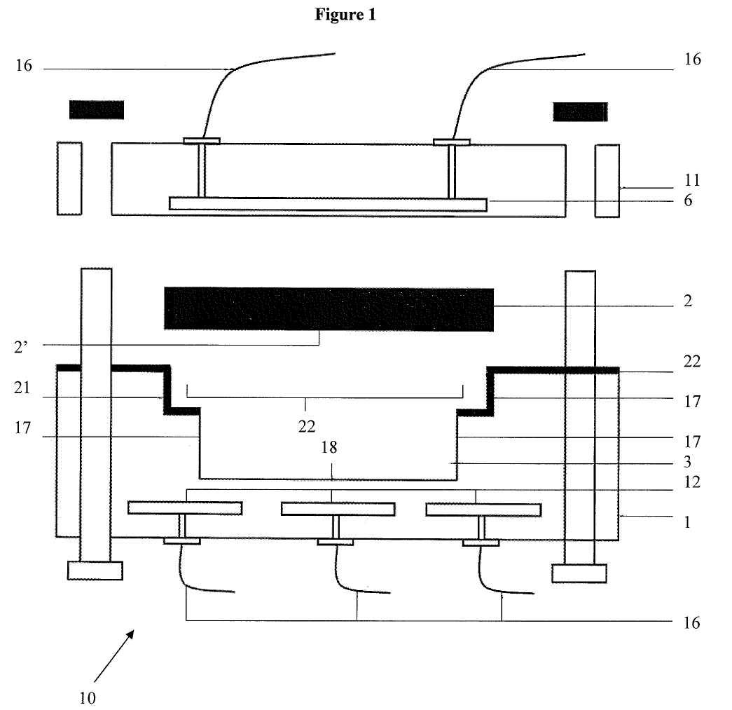

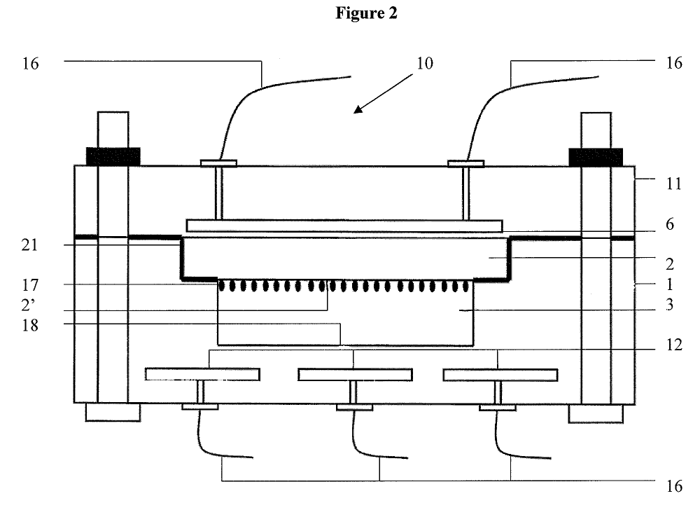

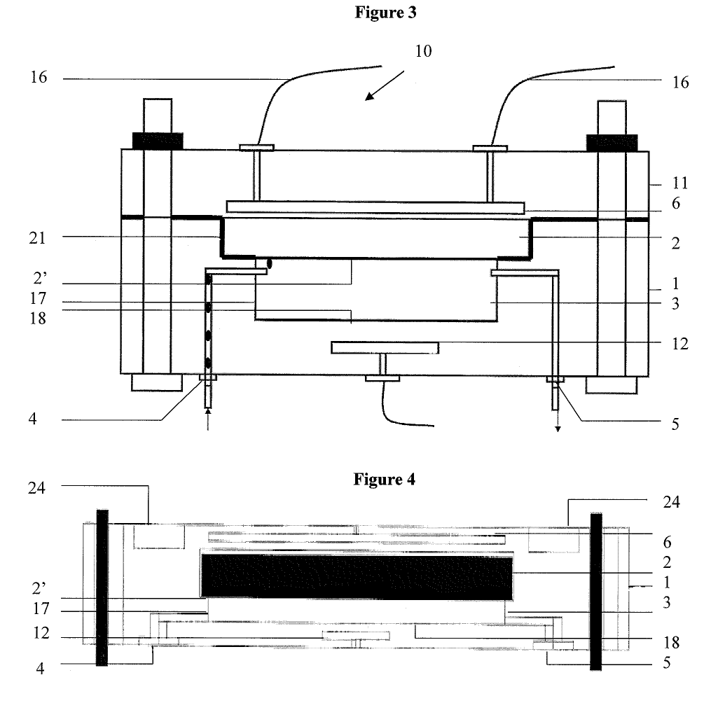

As shown in FIGS. 1-2, one embodiment of a microreactor 10 of the present invention may include a base 1 which defines at least one channel 3 therein. Each channel 3 is provided with at least one reactant inlet 4 and at least one reactant outlet 5, shown in FIGS. 3-4. Optionally, microreactor 10 may include at least one heating element 6 which may be any suitable heating element such as an electrical resistance heating element 6 provided with electrical leads 16, as shown in FIG. 1. A substrate 2 is provided to fit into a substrate receiving area 22 formed in base 1. Optionally, microreactor 10 may also include additional conventional elements to facilitate the interaction between substrate 2 and a chemical reactant, monitor and analyze the deposition process or deposition products and/or otherwise enhance or further control deposition.

Channel 3 is designed to have particular structural dimensions suitable to facilitate deposition. In an exemplary embodiment as shown in FIG. 1, channel 3 may include a pair of side walls 17 and a bottom 18 that define a chamber when substrate 2 is fitted into substrate receiving area 22 formed in base 1. The side walls 17 may be straight, curved or may have any geometric configuration. In an alternative embodiment, channel 3 may form a chamber from one continuously curved surface, such as a U shaped, semi-circular shaped, or semi-elliptical shaped trough. Additionally, the dimensions of the channel may be uniform or may vary along the length of the channel. Microreactor 10 may also be provided with a pre-mixing chamber for mixing the reactants prior to their introduction into channel 3. A suitable pre-mixing chamber may include a conventional mixing or micromixing device and may be, for example, a long, thin channel which promotes intimate mixing of the deposition reactants.

Base 1 may be fabricated from any suitable conventional material. In an exemplary embodiment, base 1 may be fabricated from aluminum, aluminum borosilicates, low temperature co-fired ceramic, stainless steel, polymethylmethacrylate, Teflon®, and combinations thereof. Preferably, base 1 is fabricated from a material that does not react with the chemicals used in the chemical deposition reaction. More preferably, base 1 may be fabricated from a chemically inert material.

As shown in FIG. 3, base 1 may define a plurality of channels 3 which may be used to carry out several deposition reactions in parallel, for creating a patterned deposition product, for high throughput screening to determine the conditions for optimal deposition, or for fabrication of a material library using a high throughput screening device.

As shown in FIG. 1, substrate 2 may be removably associated with base 1 and designed to cover at least a portion of channel 3 to form a reaction chamber. Microreactor 10 may be designed such that substrate 2 or a catalyst seeded on substrate 2 may interact with a chemical reactant to enable deposition. In an exemplary embodiment, substrate receiving area 22 may be provided with a sealing device or sealant, such as a gasket or O-ring, to create an airtight and/or liquid tight seal 21 between base 1 and substrate 2 when substrate 2 is in place for the deposition reaction. This seal 21 creates a closed system that enables control of process variables such as temperature and pressure in microreactor 10.

In an exemplary embodiment, channel 3 and substrate 2 may be designed to have a high ratio of the surface area of the substrate (S_{sub}) to the volume (V) of the channel 3 in order to enable high yield deposition. A high S_{sub}/V ratio is desired to minimize the travel distance for mass transfer by minimizing the distance between the substrate surface and the reactant. The substrate-channel complex may be designed such that the chemical reactant entering channel 3 need only travel, at most, only a short distance in order to interact with the substrate or a catalyst deposited on the substrate, thereby minimizing or eliminating the problem of bulk precipitation of the chemical reactant. High S_{sub}/V ratios, therefore, facilitate chemical reactant-substrate interaction and increase deposition yield. In an exemplary embodiment, the microreactor may be capable of producing a single pass enhanced percentage deposition yield of about 20% to about 100%, more preferably, about 50 to about 100% and most preferably, about 75% to about 100%. These yields are high relative to a conventional single pass CBD process depositing on the same substrate and can be obtained using only a single pass of the deposition reactants through the microreactor. Potentially higher deposition yields may be obtained by use of a recycle stream to recycle deposition reactants to the microreactor for two or more passes. Deposition yields will vary depending upon the specific materials used in the deposition process. However, it is expected that the microreactor 10 of the present invention will provide consistently higher single pass deposition yields than are obtained in conventional batch CBD processes independent of the deposition material employed.

A high S_{sub}/V ratio also reduces the amount of waste, such as precipitated chemical reactant, generated by the deposition process and minimizes the amount of chemical reactant necessary for performing deposition by utilizing a greater portion of the chemical reactant than would have been used in a comparable CBD process. In an exemplary embodiment, the microreactor reduces the amount of generated waste in comparison to standard CBD methods by a factor of about 1 to 30, more preferably, by a factor of about 5 to 30, and most preferably, by a factor of about 15 to about 30. Generated waste is typically comprised of unreacted deposition precursor material as well as solids that may be formed at locations in the reactor away from the substrate surface, e.g. in the reaction media or on the side walls 17 or bottom 18 of channel 3. The degree of waste reduction also depends significantly on the deposition yield of the deposition process. Processes with higher deposition yields offer less potential for waste reduction if operated in a microreactor than processes with lower deposition yields. Moreover, a high S_{sub}/V ratio also minimizes heat loading and enables precise temperature control of the microreactor, which in turn controls the rate of deposition and affects the morphology and microstructure of the film. In exemplary embodiments, the S_{sub}/V ratio is maximized by minimizing the distance from the surface 2′ of substrate 2 to bottom 18 of channel 3, thereby minimizing the area of side walls 17 relative to the area of the surface 2′ of substrate 2.

Thus, suitable channels 3 provide an average distance between surface 2′ of substrate 2 and bottom 18 of channel 3 of from about 0.1 to about 5 mm. More preferably, the average distance from the surface 2′ of the substrate 2 to the bottom 18 of channel 3 is from about 0.2 to about 2.0 mm, and most preferably, from about 0.5 to 1.5 mm. It is also possible to replace bottom 18 of channel 3 with a second substrate 2, as discussed below. In such case, the distance is measured from the surface 2′ of one substrate 2 to the surface 2′ of the second substrate 2. In this embodiment, larger distances can be employed since the largest actual distance from the chemical reactant to the surface 2′ of the substrate 2 in this case is half the distance between the substrate surfaces since substrates form both the top and bottom of channel 3.

Microreactor 10 may further include at least one heating element 6 that may be operatively associated with substrate 2 to enable or facilitate chemical deposition. Preferably, heating element 6 heats only substrate 2 thereby creating a temperature gradient between the surface of the substrate and other locations within channel 3. In an exemplary embodiment as shown in FIG. 1, the temperature gradient is about 5° C. to about 25° C., more preferably, about 5° C. to about 20° C. and most preferably about 10° C. to about 20° C. from the top to the bottom of the reactor. Optionally, heating element 6 may be covered with an insulator to maximize energy efficiency. In an exemplary embodiment, heating element 6 may be removably associated with substrate 2 to enable transfer of heat. More preferably, heating element 6 may be embedded in cap 11, such that heat may be transferred when cap 11 is positioned as shown in FIGS. 2-3. The temperature gradient in microreactor 10 may significantly affect the deposition rate since a temperature increase of about 10° C. can double the deposition rate of some of the materials of interest for the present invention and thus increase deposition yield and reduce waste. In addition, use of a seeded substrate can favor deposition on the substrate over deposition in the reaction media or on the side walls 17 or bottom 18 of channel 3 to also increase deposition yield and reduce waste. Combinations of a seeded substrate and a temperature gradient may further increase deposition yield and reduce waste.

Microreactor 10 may also include a number of optional elements. As shown in FIGS. 1-2, microreactor 10 may optionally include a cap 11 for clamping the entire microreactor assembly to prevent leakage. In an exemplary embodiment, cap 11 may be fabricated from aluminum, aluminum borosilicates, LTCC and combinations thereof. Cap 11 may also have a suitable, conventional fastening or fixation mechanism or configuration that is capable of securing cap 11 to base 1 thereby trapping substrate 2 in substrate receiving area 22 and, optionally, exerting additional downward force on substrate 2 to enhance the seal 21 provided between substrate 2 and substrate receiving area 22. Any standard removable fastening means may be appropriate, including clasps, hooks, clamps, friction fit, threaded mechanisms or combinations thereof.

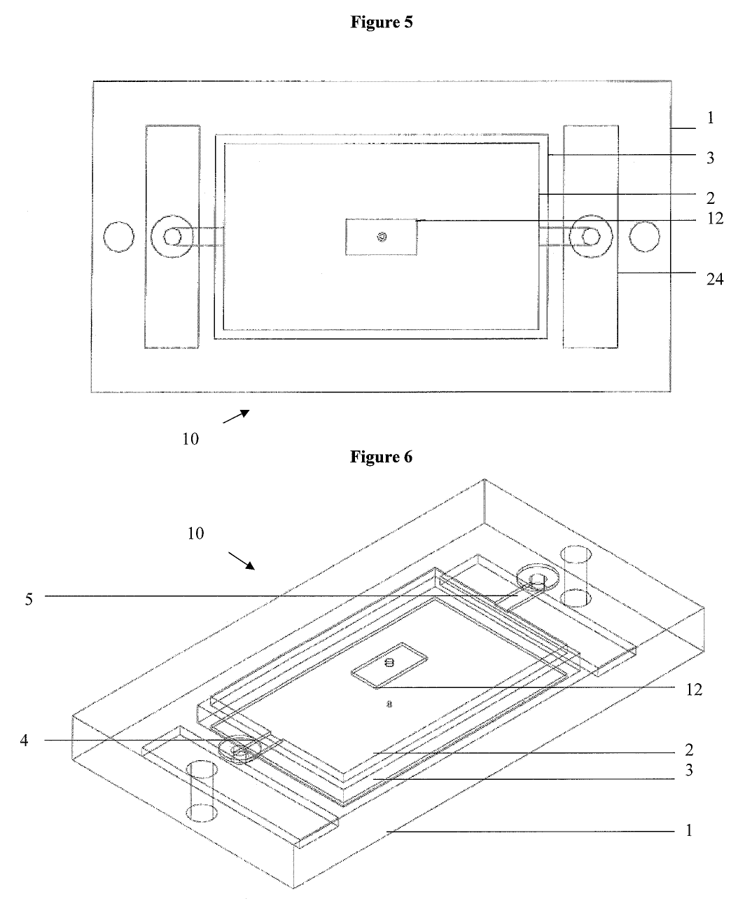

As shown in FIGS. 5-6, microreactor 10 may be provided with isolation chambers 24 for providing a barrier for heat transfer away from channel 3 via the material that forms microreactor 10. In this manner, the energy efficiency of the microreactor 10 can be improved.

Microreactor 10 may also optionally include a wide variety of tools and/or sensors 12 for in situ monitoring and analysis of the deposition process and deposition products. In an exemplary embodiment, microreactor 10 may include at least one spectroscopy probe, at least one optical probe, at least one temperature probe, at least one voltammetry probe, or a combination thereof. Preferably, microreactor 10 includes a plurality of tools provided for monitoring various environmental conditions relevant to the deposition reaction. For example, a probe for Raman spectroscopy may be included to analyze the chemistry of the chemical deposition products. FIGS. 1-2, in particular, show a plurality of thermistor sensors 12. A voltmeter may be connected to electrodes incorporated in the reactor for voltammetry and electrochemical impedance spectroscopy. Additionally, microreactor 10 may incorporate optical diagnostic instruments, such as embedded optical fibers or windows, to enable optical monitoring of reflectance and photoluminescence. Incorporation of such devices in microreactor 10 may be useful for monitoring the deposition process as well as for forming a part of a high throughput screening apparatus where one or more of the monitored parameters may be varied for screening purposes.

In one embodiment, the microreactor 10 of the present invention is run in batch mode. In this embodiment, reactant is provided to channel 3 and retained for a defined time period in channel 3 to permit deposition. Once sufficient deposition is achieved, the reactant is removed from channel 3 and the batch deposition process is complete.

In another embodiment, the microreactor 10 may be operated in a repeated batch mode which is the same as the batch mode above, except that two or more batches of reactants are run to accomplished the desired deposition. Thus, after the first batch of reactant is removed from microreactor 10, a second batch of reactant is introduced into channel 3 and retained for a defined time period in channel 3 to permit deposition. Once sufficient deposition is achieved, the second batch is removed from channel 3 and one or more additional batch processing steps may be carried out.

In another embodiment of the invention, the functionality of microreactor 10 may be further enhanced by enabling a continuous flow of a chemical reactant through microreactor 10, optionally in combination with a recycle of the used chemical reactant back to microreactor 10. Continuous operation of microreactor 10 enables a number of additional features and uses of the invention, such as the ability to use microreactor 10 as part of a high throughput screening system and/or to fabricate a high throughput screening material library.

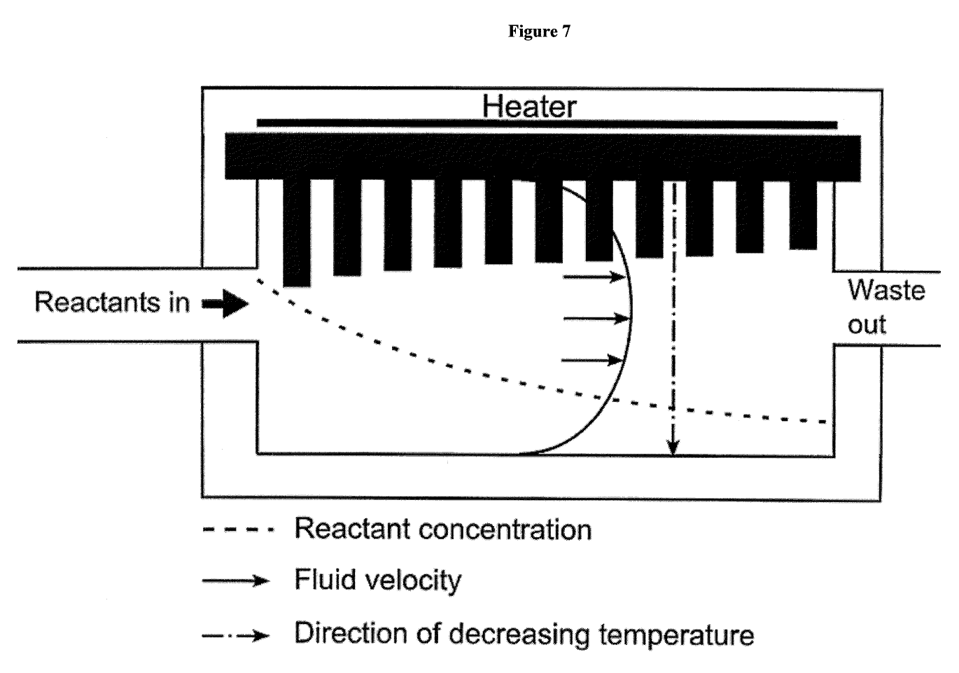

Inlet 4 and outlet 5 may be placed at any location in microreactor 10 that enables the chemical reactant to contact and interact with surface 2′ of substrate 2. As shown in FIGS. 3-6, inlet 4 and outlet 5 may be placed at opposite ends of channel 3. Such an embodiment would enable the microreactor to be operated in either a batch or continuous flow mode, as desired, since outlet 5 could be closed to allow filling of the channel 3 via inlet 4 for batch mode operation. As shown in FIG. 7, the location of inlet 4 and outlet 5 at opposite ends of channel 3 may result in a concentration gradient of reactant along the length of channel 3. The concentration gradient will depend on factors such as the depth of channel 3, the flow rate of reactant, the kinetics of the deposition process, and the temperature profile of the reaction zone. As shown in FIG. 7, the concentration gradient of the reactant may result in a variation in the coating thickness at different locations on surface 2′ of substrate 2. Typically, greater coating thicknesses will develop near inlet 4 and lesser thicknesses will develop near outlet 5 where the concentration of chemical reactant is lower due to depletion of the reactant by the deposition process as the reactant moves through channel 3. This aspect of the present reactor makes it particularly suitable for use in high throughput screening systems as well as for the fabrication of material libraries using high throughput screening systems.

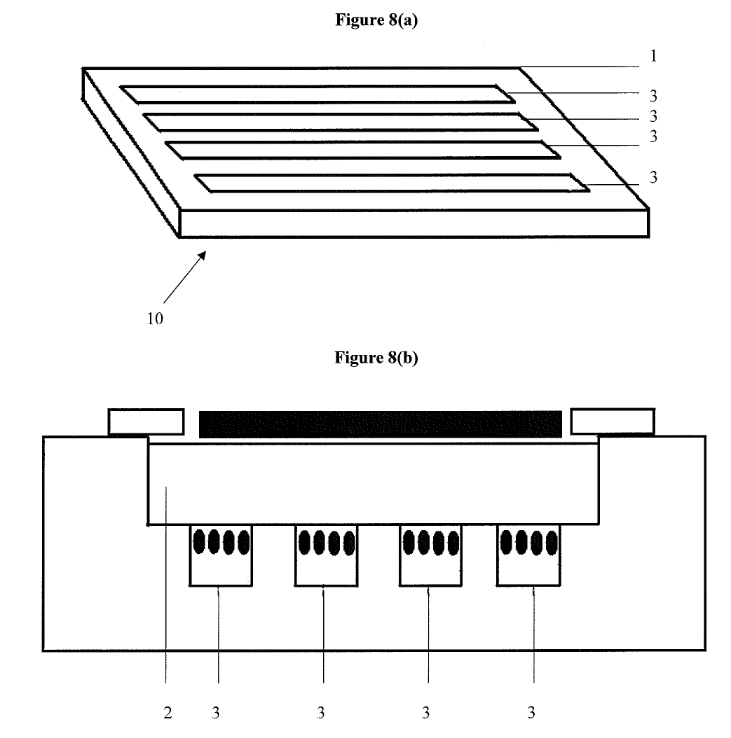

For example, a single channel 3 can be employed to deposit a plurality of coating thicknesses on a single substrate as shown in FIG. 7. This makes it possible to quickly prepare and screen a variety of coating thicknesses. If a plurality of parallel channels 3 are employed, as shown in FIGS. 8(a)-8(b), then other parameters of the coating process such as the composition and/or concentration of chemical reactants, reaction temperature, flow rate, etc. can be varied to provide additional information for screening purposes. In this manner, a skilled person can quickly optimize the deposition process due to the ability to run several depositions in parallel with variations in one or more of the parameters that are to be optimized.

In addition, microreactor 10 can be used to fabricate material libraries useful in combinatorial screening such as is described, for example, in Danielson, E., et al., “A combinatorial approach to the discovery and optimization of luminescent materials,” Nature, Vo. 389, pp. 944-948 (1997) herein incorporated by reference. In such methods, it is desirable to deposit materials on a substrate based on a pre-determined map such that the substrate contains as many as hundreds or thousands of different materials in a small area at known locations. This enables simultaneous screening of all of these materials for a particular property, such as a biological or chemical activity, the ability to bond a molecule or compound, fluorescence properties, etc. Using microreactor 10, such combinatorial arrays can be fabricated.

If the provision of a substantially uniform coating thickness over the length of channel 3 is desired, additional steps can be taken to minimize the effect shown in FIG. 7. For example, use of high concentrations of deposition material relative to the amount deposited will reduce the concentration gradient along the channel. Shortening the length of the channel will have a similar effect. Providing two or more inlets at different locations along the length of the channel can be employed to reduce concentration gradients. Also, manipulation of the residence time can reduce concentration gradients. Finally, it is possible to run reactor in reverse at the halfway point of the deposition process in order to equalize the effect of the concentration gradient over the length of the reactor.

In the case where the reactants are recycled, inlet 4 and outlet 5 may further include at least one, preferably a plurality of filters that may be used to remove any waste products, e.g. deposited materials, prior to recycle of the chemical reactants through channel 3. Additionally, inlet 4 and outlet 5 may include at least one, preferably a plurality of syringe pumps that may be used to control flow throughout the reactor.

Operating the microreactor in a continuous flow mode may be employed to eliminate the dependence of deposition thickness on the initial volume and concentration of chemical reactant that is typically present in batch CBD. As a result, continuous flow can be employed to make thicker films than can typically be achieved using batch processes. Also, longer nanowires can be fabricated in a continuous flow process, particularly if the reaction time is increased while continuously flowing fresh reactant to the microreactor. Additionally, the continuous flow embodiment may be able to more efficiently automate the chemical deposition process, minimizing the amount of work required by an operator to grow long nanowires or films, particularly in comparison to standard CBD batch processes. In contrast to the conditions involved in successively repeating CBD batch processing, the continuous flow microreactor of the present invention enables growth of films or nanowires under controlled and constant environmental conditions, such as flow rate, chemical reactant concentration, temperature and pressure. By controlling the flow rate and other environmental conditions, it may be possible to create uniform deposition across the substrate. Alternatively, the flow rate and other environmental conditions may be adjusted to create controlled variations in the deposition along the length of a channel. Therefore, it may be possible to customize deposition using the continuous flow embodiment of the present invention.

Another embodiment of the invention is directed to a microreactor that enables electrodeposition and in situ electrochemical characterization. Electrodeposition may be accomplished by applying a voltage to a conducting substrate during deposition. The application of an electric field provides a number of benefits, including synthesis of nanowires and films without pre-seeding, enhancing the rate of deposition of nanowire or film growth, and enabling the incorporation of dopants that are not thermodynamically favorable in the fabrication process (Cui, J. B. and Gibson, U. J., “Enhanced nucleation, growth rate, and dopant incorporation in ZnO nanowires”, Journal of Physical Chemistry B 109, 22074 (2005); Cui, J. B. and Gibson, U. J., “Electrodeposition and room temperature ferromagnetic anisotropy of Co and Ni-doped ZnO nanowire arrays”, Applied Physics Letters 87 (2005) herein incorporated by reference). Notably, the electrodeposition microreactor may be operated in a batch mode or continuous flow mode. It is envisioned that such a microreactor may be particularly beneficial for the deposition of many semiconductors and metals from solution.

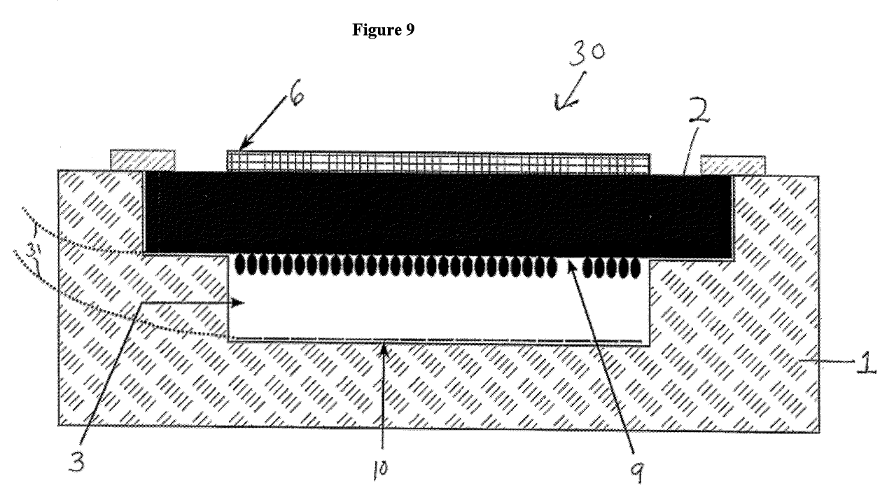

The electrodeposition microreactor 30, as shown in FIG. 9, may include essentially the same structure as that of the standard microreactor but may further include at least two electrodes, a first substrate electrode 9 and a second counterelectrode 10 that are capable of generating an electric field. Electrode 10 may have any structure or configuration and may be fabricated from any conductive material. Additionally, electrode 10 may be placed at any location in or on the microreactor that would enable the generation of a suitable electric field to provide the driving force for the deposition. Each electrode 9, 10 may include electrical leads or contacts 31 for receiving a voltage from an electrical source. The connections to both electrodes 9, 10 may be made through electrical vias in the microreactor walls. Electrodeposition microreactor 30 preferably also includes a heater 6 and may optionally include a reference electrode, not shown.

In an exemplary embodiment, the first electrode 9 may be substrate 2, and counterelectrode 10 may be embedded within or located adjacent to the bottom 18 of channel 3. Preferably, electrode 10 is configured as a wire mesh or plate, and first electrode 9 is a conducting substrate, such as F:SnO₂ or ITO transparent conducting oxide and the counterelectrode may be fabricated from Pt (Lowe, H. and Ehrfeld, W., “State-of-the-art in microreaction technology: concepts, manufacturing and applications”, Electrochimica Acta 44, 3679 (1999); Llopis, X., Ibanez-Garcia, N., Alegret, S., and Alonso, J., “Pesticide determination by enzymatic inhibition and amperometric detection in a low-temperature cofired ceramics microsystem”, Analytical Chemistry 79, 3662 (2007); Martinez-Cisneros, C. S., Ibanez-Garcia, N., Valdes, F., and Alonso, J., “Miniaturized total analysis systems: Integration of electronics and fluidics using low-temperature co-fired ceramics”, Analytical Chemistry 79, 8376 (2007) herein incorporated by reference).

The present invention is also directed to a method for using the microreactor to produce high yield deposition products with a relatively minimal amount of waste. Moreover, the invention is directed to a method for using the microreactor 10 as a research tool to investigate and analyze deposition products and determine an optimal deposition process. In general, these methods involve the steps of providing a microreactor 10 of the present invention wherein the substrate serves as a wall of the microreactor 10. A chemical reactant may then be introduced into channel 3 of the microreactor 10.

Chemical deposition occurs when the chemical reactant is exposed to and interacts with surface 2′ of substrate 2 or a catalyst seed on surface 2′ of substrate 2. To facilitate and/or induce chemical interaction, a temperature gradient may be created in the microreactor by applying heat to substrate 2 via heating element 6. In an exemplary embodiment, heat may be applied at a rate of about 5° C./min or greater, preferably, about 30° C./min or greater. Optionally, substrate 2 may be pre-seeded with a catalyst or nucleation layer to induce or facilitate deposition. Substrate 2 may also be pre-seeded with one or more catalysts or nucleation layers at varying locations to create a patterned deposition. In an exemplary embodiment, after a first chemical reactant is introduced to channel 3 and binds to or becomes deposited on substrate 2, a different chemical may be subsequently introduced to synthesize a layered product wherein each layer has a different chemical composition. Once deposition of the solid products on the substrate is complete, the substrate-product complex may be removed from the microreactor and is ready for use in various applications. A similar method for chemical deposition may also be used for multiple channel microreactors.

For electrodeposition, a voltage may be applied to the electrodes of the microreactor to create an electric field to provide a driving force for deposition. Notably, electrodeposition may be accomplished either with or without pre-seeding substrate 2.

In an exemplary embodiment, the chemical deposition or electrodeposition process further includes the procedure of doping deposited material with suitable dopants or forming ternary compounds to alter the material properties including the conductivity, band gap and magnetic properties. For example, suitable dopants for ZnO may be Al and Ga. The dopant concentration may be correlated to the precursor concentrations and/or the substrate bias. This process may be used to fabricate uniformly doped as well as more functional non-uniform complex architectures.

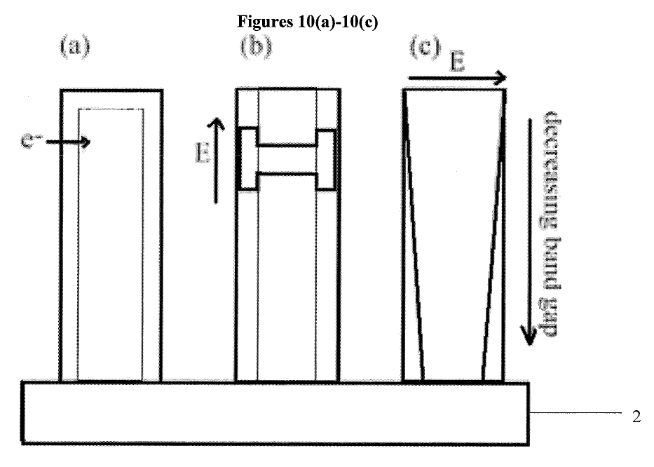

FIGS. 10(a)-10(c)) show examples of doped nanowires that may be fabricated with the microreactor of the present invention. FIG. 10(a) shows a conductive core-insulating shell nanowire. FIG. 10(b) shows a semiconductor nanowire with engineered core-shell band structure. FIG. 10(c) shows a nanowire with axially-graded band gap. By using the dopant concentration to make the nanowire conductivity and band gap dependent upon the synthesis conditions, it may be possible to customize nanowires with the desired optoelectronic properties.

Both the chemical deposition and electrochemical deposition methods of the present invention produce a high deposition yield that is considerably larger than that achieved by standard CBD methods. Additionally, the method also achieves a substantial reduction in waste and waste solvent generation relative to standard CBD methods, which may be particularly important with respect to deposition processes that require expensive or toxic chemical reactants.

The microreactor of the present invention may be operated in either a batch or continuous flow mode, as discussed above. When operated in continuous flow mode, a stream of excess chemical reactant and waste products exit channel 2 through flow channel 8. The stream may subsequently be recirculated and reintroduced to channel 3, if desired. Preferably, waste products may be filtered from the stream prior to being reintroduced into channel 3. In an exemplary embodiment, the continuous flow microreactor may be operated at a fast flow rate to produce nanowires having substantially uniform lengths throughout the reaction channel. Exemplary fast flow rates may be greater than about 1.5 mL/hr, preferably, greater than about 3 mL/hr. Flow rates required to achieve nearly uniform deposition will depend on reaction kinetics and reactor geometry.

The microreactor affords the opportunity to monitor and analyze the deposition process and the material and optoelectronic properties of the resultant deposition products using sensors, such as optical probes, spectroscopy probes and/or voltammetry and electrochemical impedance probes. Based on the information obtained from the sensors, it is possible to rapidly determine the optimal microreactor environmental conditions necessary to optimize the deposition process. In an exemplary embodiment, a continuous flow microreactor may enable real time analysis of the deposition process as well as enable real time material characterization of the deposition products.

By using a multi-channel continuous flow microreactor it may be possible to further enhance process optimization by simultaneously experimenting with multiple factors such as temperature, flow rate, chemical reactant composition, multiple or layered chemical reactants, chemical reactant concentration and deposition duration. By using each channel to test varying conditions, it is possible to observe how each unique set of conditions affects deposition both among and along the different channels. The affects on deposition may be compared both along and among different channels of the substrate to analyze the dependence of material properties on process conditions. Photoluminescence and high throughput testing can be used determine the optimal chemical reactants and environmental conditions for optimizing deposition. This method may be particularly useful for ternary compounds, such as Zn₍ₓ₎Cd₍₁₋ₓ₎O and CuInSe₂, wherein prediction of mixture properties based on pure compound properties may be difficult. The foregoing embodiments enable experimental multiplexed growth, rapid material characterization and high throughput screening.

In another embodiment, the present invention can be employed to fabricate two-dimensional (2D) combinatorial arrays. In this embodiment, the chemical deposition may, for example, be varied along the length of the channel depending upon factors such as the available concentration of a chemical reactant for binding to the substrate. Deposition of the substrate therefore may vary as a function of spatial position along the length of the channel and from one channel to the next. These variations in deposition can be used to create a 2D combinatorial array.

The microreactor of the present invention is advantageous because it produces high deposition yields, minimizes waste generated by the deposition process, and may be used to fabricate deposition products having custom designed morphology and properties since it permits relatively precise temperature control in the reactor. The microreactor is also ideal research tool for investigating the reaction kinetics of semiconductor and nanomaterial deposition. Understanding of reaction mechanisms combined with removing transport limitations by the high S_{sub}/V ratio will allow precise control of semiconductor morphology and properties while dramatically improving yield. Additionally, by operating the microreactor in continuous flow mode, it is possible to create a combinatorial chemical library to investigate and analyze the optimal deposition process and conditions.

The microreactors of the present invention may be used for a wide variety of applications, including producing semiconductors materials and nanomaterials for the optoelectronics, laser, photovoltaic, biosensor, and chemical sensor industries. Because the microreactor may be capable of fabricating customized deposition materials, it may be particularly well suited for generating components of photovoltaic cells such as anti-reflective layers, transparent conducting oxide films, absorber layers and buffer layers, nanostructured solar cells, gas sensors, and photocatalysis. The microreactor may also be an informative research tool enabling in situ monitoring with electrochemical and optical probes. Specifically, it is envisioned that it may be useful for analyzing the kinetics of a deposition process and for producing combinatorial arrays that can be used to rapidly screen materials.

### EXAMPLES

### Example 1

### Batch Microreactor

In an exemplary embodiment, ZnO nanowire arrays were synthesized using the novel microreactor of the present invention operated in batch mode. ZnO was selected due to its wide band gap (E_{g} 3.37 eV) and large exciton binding energy (60 meV), which enable diverse applications in UV lasers, sensors, transparent conducting coatings, and nanostructured photovoltaics. Synthesized under batch operation mode, the resultant percentage deposition yields of the synthesized ZnO nanowire arrays exceeded 48% and reduced the waste solvent volume by a factor of 10 in comparison to the amount of waste produced by CBD in a conventional reactor (McPeak, K. M. and Baxter J. B, “Microreactor for High-Yield Chemical Bath Deposition of Semiconductor Nanowires: ZnO Nanowire Case Study,” Industrial & Engineering Chemistry Research (2009)). The ZnO nanowires arrays were fabricated using the batch microreactor shown in FIG. 2, which includes an aluminum base with a 1.2 mm deep channel. The batch microreactor had an S_{sub}/V ratio of 0.78 mm⁻¹.

The batch microreactor also included two openings which were used to fill the channel with a chemical bath using a syringe. The openings were subsequently sealed with silicone plugs to prevent evaporation. Within the channel, the chemical bath composition reacted with a glass substrate, about 18 mm×35 mm, pre-seeded with a thin polycrystalline ZnO film that covered the channel. The channel was lined with a gasket to create an airtight and watertight seal with the pre-seeded substrate. An insulated contact heater was pressed against the back surface of the substrate to create a temperature gradient that facilitated chemical deposition. A uniform application of heat was then applied across the entire substrate to provide the isothermal temperature required for nanowire growth over large areas. The entire batch microreactor assembly was clamped together to prevent leakage.

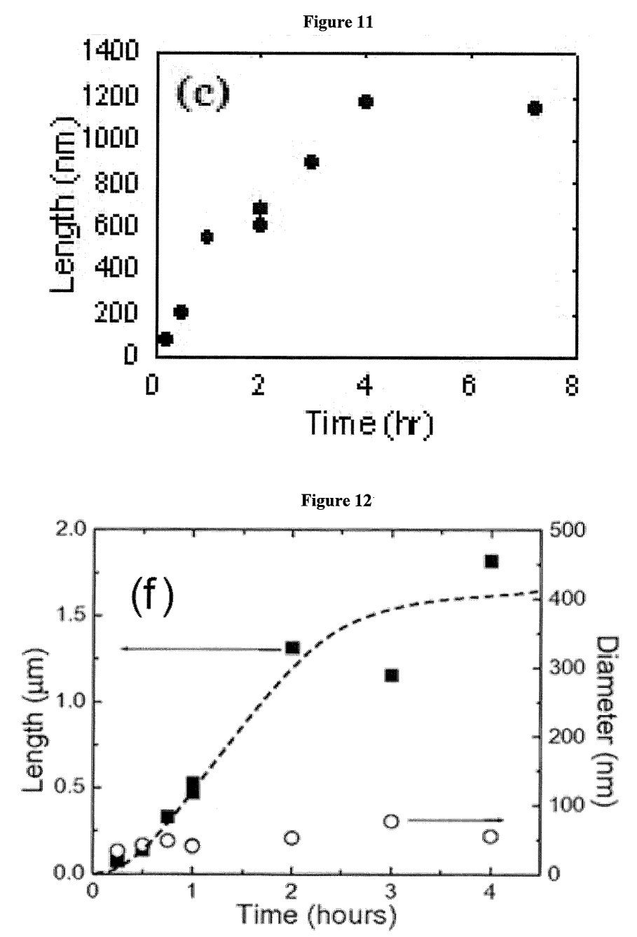

Dense arrays of vertically aligned nanowires with diameters of 60-100 nm were grown in the batch microreactor by controlling the contact heater to achieve a substrate temperature of 90° C. The ZnO nanowires were grown in aqueous solution of 0.025 M zinc nitrate and 0.025 M hexamethylenetetramine (HMT). After three hours, the nanowires grew to about 900 nm in length with uniform diameters of about 80 nm and a volume fraction of 35%, as shown in FIG. 11. The synthesized nanowires had similar dimensions to conventional CBD nanowires, demonstrating that the batch microreactor is capable of appropriately growing nanostructured semiconductors. The nanowires were well crystallized and highly oriented along the c-axis direction. Differences in alignment and density between nanowire arrays resulted primarily from the method of seeding and not as a result of the nanowire growth technique. Nanowire length increased quickly in the first three hours before eventually terminating when the reactants were depleted. No induction period was observed during this process, which, without wishing to be bound by theory, may be due to the rapid heating of the small batch microreactor volume.

The percentage deposition yield calculated for the batch microreactor was over 48% with heating rate of 8° C./min. The microreactor yield was more than 15 times higher than that of the conventional reactor, and the volume of waste solvent was also reduced by a factor of 15. The deposition yield of the ZnO nanowires was measured by using an inductively coupled plasma mass spectrometry (ICP-MS, Agilent 7500a). Without wishing to be bound by theory, it is believed that the high surface-to volume geometry of the batch microreactor produced high yields by eliminating mass transport limitations. Little to no precipitation was visible in the solution after the reaction was complete, and there was very little deposition on the non-substrate reactor walls. The lack of deposition on the other reactor walls arises from two factors: (1) the walls were not seeded with a ZnO thin film and (2) only the substrate was heated creating a temperature gradient across the solution in the channel that resulting in a far reactor wall temperature of 80° C., wherein the lower temperature results in slower kinetics and less growth on the reactor wall as well as less precipitation. Additionally, the batch microreactor had less wall area to deposit on.

With this density and alignment of the layer, the produced nanowires were limited to 1.1 μm length because of the limited initial charge of reactants in the narrow channel.

### Comparative Example A

### ZnO Nanowire Array Fabricated Using a Conventional CBD Vial Reactor

For purposes of comparison with Example 1, ZnO films and nanowire arrays were also synthesized using conventional CBD methods in a glass vial reactor. The ZnO nanowire arrays, grown in aqueous solution of 0.025 M zinc nitrate and 0.025 M HMT at 90° C., also grow in dense vertical arrays with c-axis orientation. (McPeak, K. M. and Baxter J. B, “Microreactor for High-Yield Chemical Bath Deposition of Semiconductor Nanowires: ZnO Nanowire Case Study,” Industrial & Engineering Chemistry Research (2009) and Baxter, J. B., Walker, A. M., van Ommering, K., and Aydil, E. S., “Synthesis and Characterization of ZnO Nanowires and their Integration into Dye Sensitized Solar Cells”, Nanotechnology 17, S304 (2006)). The resultant nanowires were well-faceted hexagonal single crystals wurtzite with growth along the c-axis, as determined by x-ray diffraction and transmission electron microscopy, whose diameter and alignment was controlled by a combination of nanowire growth conditions and the seeding procedure.

FIG. 12 illustrates the length of the nanowires grown in a conventional reactor versus time. The process had an induction time of about 10 minutes during which complexation in the bath reached a steady state. After the induction period, there is a steady growth period of several hours, after which growth slows significantly as reactants are depleted. Nanowires grew to lengths of about 1 μm with a single CBD batch. However, placing the nanowire substrate into a fresh batch of the precursor solution produced further nanowire growth. After eight batch cycles, the nanowires had lengths up to about 8 μm and diameters of about 200 nm. Although the multiple batch cycle nanowire arrays have the high surface areas and well-defined geometry that is desirable for many applications, the repeated batch CBD process is tedious, labor intensive and can lead to defects in the semiconductor at the batch transition points.

During this experiment, it was determined that the nanowire growth mechanism was highly dependent upon the CBD solution conditions. Under high supersaturation, nanowires grow at about 10 nm/min using a 2D nucleation and growth mechanism. At low super saturation, nanowires undergo a slow spiral growth. Photoluminescence measurements demonstrated that the nanowires showed strong band edge emission at 385 nm with some deep level defect emission centered around 500 mm.

A primary disadvantage of the CBD was the vast precipitation in solution as well as deposition on the walls of the glass vial that result in very low percentage deposition yield of about 3% which is much lower than the yield of the microreactor. By comparison, the batch microreactor yield was more than 15 times higher than the CBD yield, primarily due to its high surface to volume ratio which resulted in a 15-fold reduction in waste. Yield, Y, is calculated by equation 1, below:

$$Y = \frac{LA ϕρ}{{C}_{O} VM} , \qquad ( Equation 1 )$$

where L is the average nanowire length, A is the seeded area of the substrate, φ is the solid volume fraction of the nanowire array, ρ is ZnO density, C₀ is the initial concentration of Zn in solution, V is the volume of the bath, and M is the molecular weight of ZnO. The 3% yield was calculated for 0.5 μm long nanowires covering the seeded side of a 25 mm×35 mm glass substrate with a volume fraction of 50%, grown from a 25 mL bath with initial concentration 0.025 M zinc nitrate.

### Example 2

### Batch Microreactor

In an experimental study, the effect of different heating rates, specifically a heating rate of the contact heater of about 34° C./min and about 8° C./min, on the growth of nanowires formed in the microreactor of the present invention operated in batch mode was investigated. (McPeak, K. M. and Baxter J. B, “Microreactor for High-Yield Chemical Bath Deposition of Semiconductor Nanowires: ZnO Nanowire Case Study,” Industrial & Engineering Chemistry Research (2009)) The batch microreactor produced dense arrays of well-aligned single-crystal ZnO nanowire arrays having diameters of 80-100 nm. The high surface-to-volume ratio of the batch microreactor and short mass transport distance produce high ultimate deposition yields of about 35% to about 50% with fast and slow heating rates, respectively, with minimal loss due to precipitation or deposition on unheated reactor walls. The low thermal mass of the batch microreactor and heated substrate on which the nanowires were grown further increased the deposition rate by enabling rapid heating, which reduces induction time.

The substrate on which the ZnO nanowires were grown was fabricated from standard 1 mm thick soda lime glass slides and had a dimension of about 25 mm in width by about 45 mm in height. Prior to use, the substrates were cleaned by sonication at 60° C. for 10 min in an acetone-isopropanal-DI water bath and subsequent sonication for 10 min in DI water alone. The substrates were then seeded with a thin ZnO film by dip coating the slides in an ethanol solution containing 0.375 M zinc acetate and 0.375 M monoethanolamine (MEA) at a withdrawal rate of 56 mm/min (Ohyama, M.; Kozuka, H.; Yoko, T. Sol-gel preparation of ZnO films with extremely preferred orientation along (002) plane from zinc acetate solution (Thin Solid Films 1997, 306, 78-85; Sagar, P.; Shishodia, P. K.; Mehra, R. M. Influence of pH value on the quality of sol-gel derived ZnO films. Appl. Surf. Sci. 2007, 253, 5419-5424). The substrates were then annealed on a hotplate at 450° C. for 20 min. The resulting ZnO seed films had a polycrystalline structure with a thickness of about 40 nm and a grain size of about 20 nm. The pre-seeded substrate was then used to form a wall of the batch microreactor, as shown in FIG. 2. The substrate was faced downward in the batch microreactor to prevent any precipitate from settling onto the growing nanowires and functioned as a scaffold on which the ZnO nanowires may grow.

The reaction channel in the batch microreactor shown in FIG. 2 was fabricated to have a dimension of about 18 mm in width by about 35 mm in length and by about 1 mm in height. The deposition channel was machined from 6061 aluminum, and two small holes in the batch microreactor operate to fill the deposition channel with solution. The glass substrate, pre-seeded with ZnO, was pressed against a silicone gasket to seal the deposition channel. A kapton contact heater (Minco), which is attached to a piece of plexiglass by double-sided thermally conductive tape, was pressed against the back surface of the substrate. The whole assembly was then clamped together to prevent leakage.

In the present study, the deposition channel was rapidly filled with 0.8 mL of a precursor solution using a syringe. To form ZnO nanowires, the aqueous precursor solution was formulated from 0.025 M zinc nitrate and 0.025 M hexamethylenetetramine (HMT) at 90° C. For synthesis of ZnO films, the concentration of each precursor was doubled to 0.05 M (Govender, K.; Boyle, D. S.; Kenway, P. B.; O'Brien, P. Understanding the factors that govern the deposition and morphology of thin films of ZnO from aqueous solution. J. Mater. Chem. 2004, 14, 2575-2591). Both solutions were degassed by Helium sparging for 30 minutes prior to being pumped into the batch microreactor. The holes were then sealed with silicone plugs to prevent evaporation of the precursor solution. Temperature measurements of the batch microreactor's aluminum base were combined with a 1-D heat transfer model with experimentally determined heat transfer coefficients to heat the substrate-solution interface to 90° C. In this study, ZnO nanowire growth was studied at contact heating rates of about 34° C./min and about 8° C./min. These heating rates were linear approximations of the first order temperature response to heating during the induction period for the batch microreactor. The temperature increased more slowly as it approaches 90° C. The step of heating the sealed batch microreactor causes a slight positive pressure to build up in the deposition channel, which helped to avoid outgassing and facilitated the elimination of bubble formation on the substrate surface.

In this experiment, the deposition yield of ZnO on the substrate, as compared to initial Zn²⁺_{(aq)} in solution, was measured using an inductively coupled plasma mass spectrometry (ICP-MS, Agilent 7500a). Aliquots of the precursor solution were removed from the batch microreactor upon completion of the reaction time. These samples were then immediately centrifuged to separate precipitate from aqueous zinc ions and complexes, and precipitate-free supernatant was pipetted into a transfer tube for ICP-MS analysis. To determine the mass of ZnO deposited on the substrate using ICP-MS, the backside of each substrate was first swabbed with HNO₃ in order to remove residual ZnO seed layer from the dip coating step. The substrates were then placed in a PFA dish (Savilex) and digested with 2% (v/v) HNO₃ for ICP-MS measurement, where mass of ZnO removed from the substrate is calculated from Zn²⁺_{(aq)} concentration measured in solution. Upon removal from the PFA dish, the substrate was transparent indicating complete digestion of the ZnO.

The synthesized nanowires and films were also imaged using scanning electron microscopy (SEM, Zeiss Supra 50VP). Crystal orientation was determined using X-ray diffraction (XRD, Siemens D500) with Cu Kα radiation. A micro-Raman spectrometer (Renishaw RM1000) with visible (514.5 nm) laser excitation was also used to measure the non-resonant Raman spectra, with spectra acquired in backscattering geometry at room temperature.

### 1. ZnO Nanowires and Films Produced by the Batch Microreactor

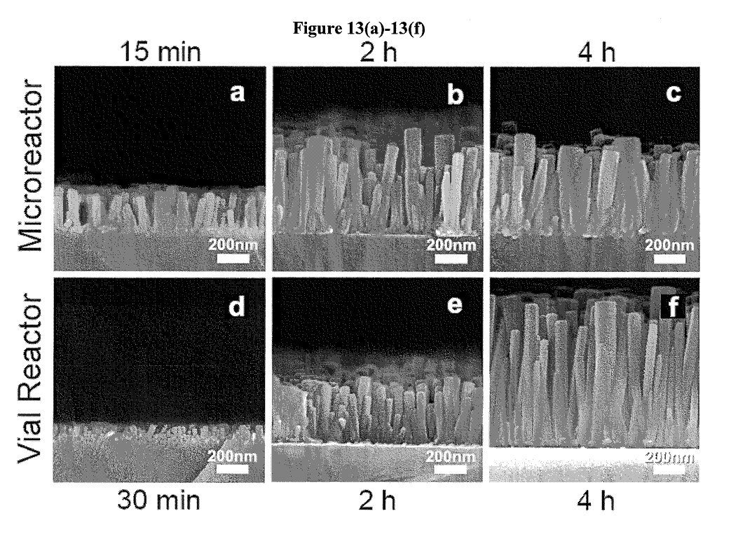

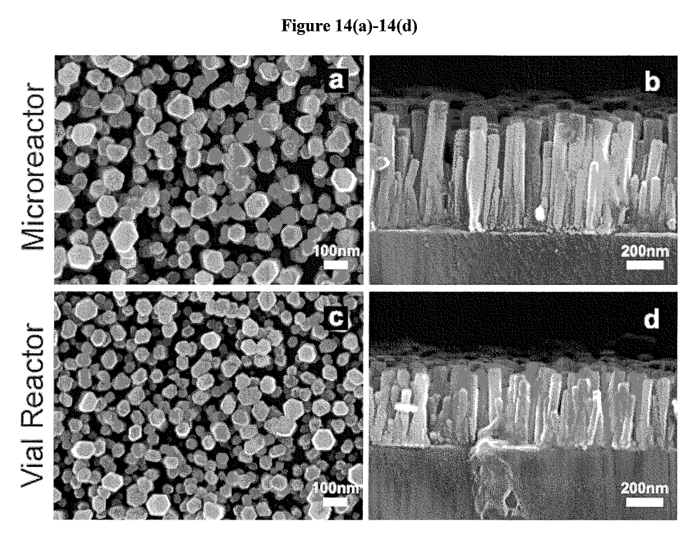

In general, the ZnO nanowires grown in the batch microreactor were very similar in morphology to those grown in conventional vial CBD reactors (Lee, Y. J.; Sounart, T. L.; Scrymgeour, D. A.; Voigt, J. A.; Hsu, J. W. P. Control of ZnO nanorod array alignment synthesized via seeded solution growth. Journal of Crystal Growth 2007, 304, 80-85: Vayssieres, L. Growth of arrayed nanorods and nanowires of ZnO from aqueous solutions (Advanced Materials 2003, 15, 464-466: Govender, K.; Boyle, D. S.; Kenway, P. B.; O'Brien, P, Understanding the factors that govern the deposition and morphology of thin films of ZnO from aqueous solution, J. Mater. Chem. 2004, 14, 2575-2591; Greene, L. E.; Law, M.; Goldberger, J.; Kim, F.; Johnson, J. C.; Zhang, Y. F.; Saykally, R. J.; Yang, P. D. Low-temperature wafer-scale production of ZnO nanowire arrays, Angewandte Chemie-International Edition 2003, 42, 3031-3034; Baxter, J. B.; Walker, A. M.; van Ommering, K.; Aydil, E. S. Synthesis and Characterization of ZnO Nanowires and their Integration into Dye Sensitized Solar Cells, Nanotechnology 2006, 17, S304-S312.). After 2 hours of growth in the batch microreactor, micrograph images showed ZnO nanowires that were hexagonal in cross-section, densely packed, vertically-aligned, about 80-100 nm in diameter and about 500 nm in length. The overall length of the nanowires was determined as a function of time in the batch microreactor. After 15 minutes in the batch microreactor, the nanowires are about 200 nm long. After 4 hours, the nanowires are about 550 nm long. Due to the fast microreactor heating rate, it was possible to produce long nanowires early in the nanowire growth stage. FIGS. 13(a)-13(f) show electron micrographs of the nanowires grown in the batch microreactor and with a conventional CBD reactor over time. FIGS. 14(a)-14(d) show the morphology and geometry of the nanowires after a period of 2 hours.

The batch microreactor was also used to synthesized ZnO thin films using 0.05 M concentrations of zinc nitrate and hexamethylenetetramine. The resultant films were about 1.4 μm thick after 3 hours of growth and had an average grain size of about 220 nm. Micrograph imaging showed that many of the columnar grains of the films had coalesced.

### 2. Deposition of the ZnO Nanowire Using the Batch Microreactor

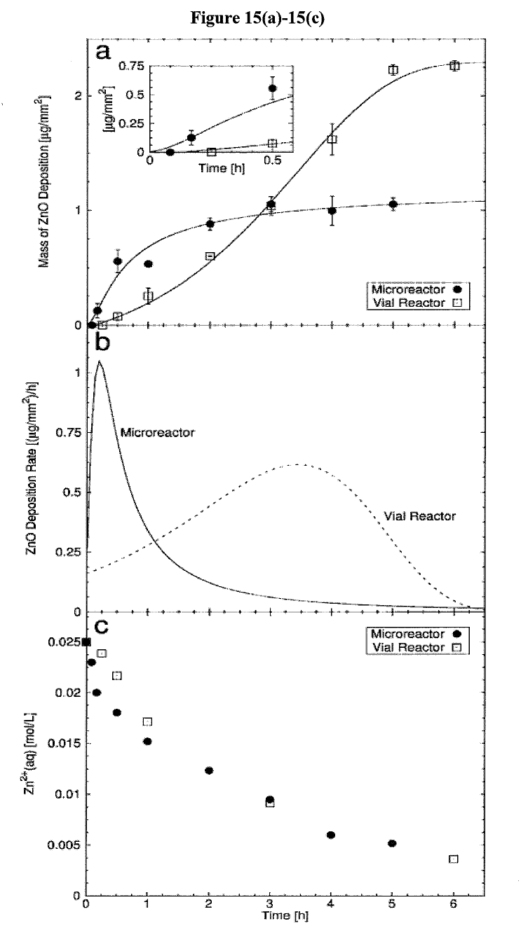

Deposition was investigated by measuring the total mass of material deposited on the substrate using ICP-MS analysis of the acid-digested ZnO deposits as a function of growth time. This involved removing the substrate from the reactor at various times, digesting the deposited ZnO in HNO₃, and analyzing the solution by ICP-MS. The average mass of the ZnO seed layer was also measured using the same method and was subtracted from the nanowire mass. FIG. 15(a) shows the mass of ZnO deposited per area of substrate at a heating rate of about 34° C./min as a function of time. The error bars in FIGS. 15(a)-15(c) reflect the standard error of the measured mass in two samples collected at each of the observed times. Nanowire deposition was first measured at about 5 minutes (Markov, I. V. Crystal Growth for Beginners. 2nd ed.; World Scientific Publishing Co.: Singapore, 2004.). The rapid heating of the substrate-solution interface in the batch microreactor reduced the induction period by about 10 min. After the batch microreactor's very short induction period, the nanowires experience a 30 min period of rapid growth followed by several hours of slower growth. The mass of ZnO deposited on the substrate in the batch microreactor saturated at 1.0 μg/mm² after about 3 hours.

SEM analysis showed that the deposited nanowires were substantially uniform in length across the substrate. During the early growth stages at about 5 min, the nanowires uniformly covered the surface of the substrate, with the exception of areas within 1 mm of the side walls of the deposition channel where the substrate temperature was lower. The substantially uniform length of the nanowires across the substrate was produced by using the batch microreactor's contact heater and horizontal orientation to eliminate any lateral temperature and concentration gradients across the surface of the substrate.

### 3. Deposition Rate of the ZnO Nanowire Using the Batch Microreactor

The ZnO deposition rate was determined by empirically fitting a function (NIST MGH10 function) to the batch microreactor's deposition versus time data and calculating its first order derivative. This fit is shown in FIG. 15(a); FIG. 15(b) shows a graph of the deposition rate as a function of time. The fast heating rate of the batch microreactor produces a fast deposition rate that rises rapidly but then decreases quickly after the first 30 minutes of growth.

### 4. Deposition Yield of the ZnO Nanowire Using the Batch Microreactor

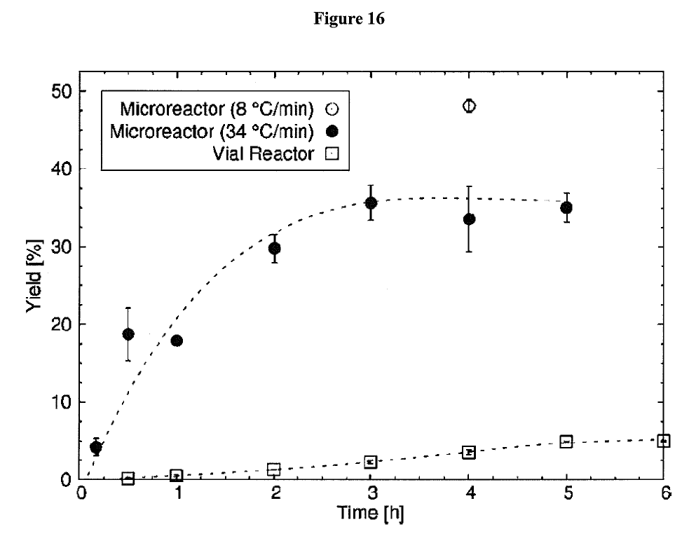

The batch microreactor also produced a high deposition yield, which was calculated by dividing the moles of ZnO deposited on the substrate at a given time, determined from FIG. 15(a), by the initial moles of Zn in the chemical bath. FIG. 16 shows ZnO nanowire yield as a function of time for the batch microreactor, with error bars based on the errors calculated in FIG. 15(a). A sequence of data was recorded for the batch microreactor with a fast heating rate of 34° C./min, while a single point at 4 hours was measured for a slower heating rate of 8° C./min. At a heating rate of about 34° C./min, the batch microreactor yield increases with time until saturating at about 37% after about 3 hours. The ultimate batch microreactor yield increased to about 48% when heated at about 8° C./min. The data suggests that faster heating increases the amount of initial precipitation in the solution and that the nucleation and growth of these precipitates competes for reactants with nanowire growth. This competition between bulk precipitation and deposition in the batch microreactor is clearly shown by the decrease in the [Zn²⁺_{(aq)}] after 3 hours (See FIG. 15(c)) even though the mass of ZnO deposited on the substrate has reached steady state (See FIG. 15(a)). Without wishing to be bound by theory, it is believed that the [Zn²⁺_{(aq)}] continues to decrease due to the continued growth of precipitates in the channel. As bulk precipitates grow, their surface area increases and creates new reaction sites for the depletion of Zn²⁺_{(aq)}. Reactants in the channel must diffuse past these increasingly large precipitates to reach the substrate. At some critical point, the rate of bulk precipitation overtakes the rate of surface deposition due to the increased probability that Zn²⁺_{(aq)} ions react on the precipitate surface before they can reach the substrate. Bulk precipitation in the batch microreactor may be mitigated by reducing the heating rate to discourage initial nucleation of precipitates at the onset of supersaturation and increase the ultimate yield.

### 5. Crystal Quality and Defect Structure of the ZnO Nanowire of the Batch Microreactor

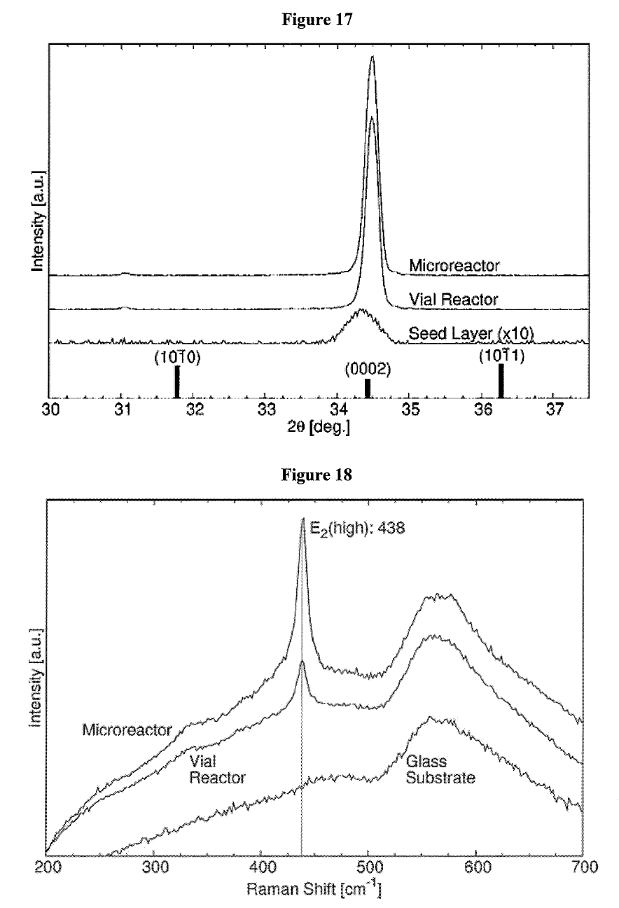

X-ray diffraction (XRD) of the nanowires grown in the batch microreactor showed a single major peak at about 34.48° that corresponds to the (0002) plane of wurtzite ZnO. 2-theta scans of the nanowires as well as the ZnO seed film are shown in FIG. 17 along with lines corresponding to peak heights of a reference wurtzite ZnO powder. Other peaks such as (10 1̅0) and (10 1̅1) that are larger than the (0002) peak in the powder diffraction pattern were not observed in the nanowire diffraction pattern, indicating that the ZnO c-axis was well-aligned perpendicular to the substrate.

FIG. 18 shows that the Raman spectra of ZnO nanowires grown in the batch microreactor exhibited a sharp peak at 438 cm⁻¹. This peak is the high frequency E₂ mode, which corresponds to the oxygen sublattice and indicates good crystal quality (Ren, T.; Baker, H. R.; Poduska, K. M. Optical absorption edge shifts in electrodeposited ZnO thin films. Thin Solid Films 2007, 515, 7976-7983). The broad peak centered at 565 cm⁻¹ is from the soda lime glass substrate. The position of the E₂(high) peak was independent of the reactor, indicating that the faster growth rate in the batch microreactor did not induce strain in the lattice.

### Comparative Example B

### ZnO Nanowire Array Fabricated Using a Conventional CBD Vial Reactor

For purposes of comparison with Example 2, ZnO nanowire arrays were also synthesized using a conventional CBD vial reactor. (McPeak, K. M. and Baxter J. B, “Microreactor for High-Yield Chemical Bath Deposition of Semiconductor Nanowires: ZnO Nanowire Case Study,” Industrial & Engineering Chemistry Research (2009)) Overall, the microreactor-grown ZnO nanowires of Example 2 had a faster initial deposition rate and substantially larger deposition yield than the ZnO nanowires synthesized using the conventional CBD vial reactor. The large deposition yield of Example 2's batch microreactor may be attributed to its high surface-to-volume ratio, which reduced transport limitations, while its faster heating rates decreased the induction time and increased initial deposition rate.

ZnO nanowires were synthesized using conventional CBD methods that involved filling a 26 mm diameter cylindrical glass vial with 27 mL of the same precursor solution as that of Example 2. The seeded substrate disclosed in Example 2 was then dropped into the glass vial so that the seeded side was angled downward at approximately 20° (Lee, Y. J.; Sounart, T. L.; Scrymgeour, D. A.; Voigt, J. A.; Hsu, J. W. P., Control of ZnO nanorod array alignment synthesized via seeded solution growth, Journal of Crystal Growth 2007, 304, 80-85.). The glass vial was then capped and placed in an oven that was preheated to 90° C. During deposition, the contents of the conventional CBD vial reactor were not mixed. The temperature of the glass vial was monitored during deposition and was found to have a heating rate of about 2.5° C./min.

The concentration of Zn²⁺_{(aq)} in the glass vial was measured using an inductively coupled plasma mass spectrometry (ICP-MS, Agilent 7500a). Aliquots of the precursor solution were removed from the glass vial upon completion of the reaction time. These samples were then immediately centrifuged to separate the precipitate from aqueous zinc ions and complexes, and precipitate-free supernatant was pipetted into a transfer tube for ICP-MS analysis. The synthesized nanowires were imaged using the same methods and equipment as disclosed in Example 2.

### 1. ZnO Nanowires Produced by the CBD Vial Reactor

In general, the morphology of the ZnO nanowires grown in the CBD vial reactor was very similar to the nanowires of Example 2, as indicated by the electron microscopy images of FIGS. 14(a)-14(d) (Lee, Y. J.; Sounart, T. L.; Scrymgeour, D. A.; Voigt, J. A.; Hsu, J. W. P. Control of ZnO, nanorod array alignment synthesized via seeded solution growth, Journal of Crystal Growth 2007, 304, 80-85: Vayssieres, L. Growth of arrayed nanorods and nanowires of ZnO from aqueous solutions, Advanced Materials 2003, 15, 464-466: Govender, K.; Boyle, D. S.; Kenway, P. B.; O'Brien, P., Understanding the factors that govern the deposition and morphology of thin films of ZnO from aqueous solution, J. Mater. Chem. 2004, 14, 2575-2591; Greene, L. E.; Law, M.; Goldberger, J.; Kim, F.; Johnson, J. C.; Zhang, Y. F.; Saykally, R. J.; Yang, P. D., Low-temperature wafer-scale production of ZnO nanowire arrays, Angewandte Chemie-International Edition 2003, 42, 3031-3034; Baxter, J. B.; Walker, A. M.; van Ommering, K.; Aydil, E. S., Synthesis and Characterization of ZnO Nanowires and their Integration into Dye Sensitized Solar Cells, Nanotechnology 2006, 17, S304-S312). After 2 hours of growth in the CBD vial reactor, micrograph images showed ZnO nanowires that were hexagonal in cross-section, densely packed, vertically-aligned, about 80-100 nm in diameter and about 380 nm in length. After 30 minutes, the nanowires were about 70 nm long. After 4 hour's, the nanowires were about 860 nm long. In comparison with Example 2, the ZnO nanowires grown in the batch microreactor were longer during the early stages of growth than that of the CBD vial reactor due to the batch microreactor's faster heating rate and shorter induction time. The smaller initial quantity of reactants in the batch microreactor, however, limited the ultimate deposition thickness compared to the nanowires of the vial reactor. Consequently, after 4 hours the length of the nanowires in the CBD vial reactor was larger than the nanowires of the batch microreactor.

### 2. Deposition of the ZnO Nanowire Produced by the CBD Vial Reactor

Nanowire deposition produced by the CBD vial reactor was first measured at about 15 minutes to allow for induction in the same manner disclosed in Example 2 (Markov, I. V. Crystal Growth for Beginners. 2nd ed.; World Scientific Publishing Co.: Singapore, 2004). After the induction period, the growth rate of the nanowires synthesized in the CBD vial reactor gradually increased over a 2 hour period, which was subsequently followed by another 2 to 3 hour period of steady growth. After about 4 to 5 hours, the deposition in the vial reactor slowed; by the sixth hour, deposition has saturated at 2.3 μg/mm². FIG. 15(a) shows the mass of ZnO deposited per area of substrate grown in the CBD vial reactor as a function of time. The error bars in FIGS. 15(a)-15(c) reflect the standard error of the measured mass collected at each of the observed times. In comparison with Example 2, the vial reactor, with its larger bath volume of 27 mL, continued to deposit ZnO on the substrate for a longer period of time than the batch microreactor. The relatively small initial quantity of reactants in the 0.8 mL bath volume of the batch microreactor limited the extent of ZnO deposition on the substrate.

In general, SEM analysis showed that the nanowires deposited by the batch microreactor were more uniform in length across the substrate than the nanowires of the CBD vial reactor, particularly during the early growth stage. This may be explained by the temperature difference in temperature between the top and bottom of the CBD vial reactor. During the first 15 minutes of heating, the top of the CBD vial reactor was about 7.5° C. hotter than the bottom. Natural convection is responsible for the temperature gradients in the vial reactor during the induction period, and these temperature differences affect the early stages of ZnO nucleation on the substrate. The top 1 cm of the solution in the vial became turbid from precipitation while the solution near the bottom of the vial stayed clear during the induction period. After 15 min, sections of the substrate closest to the top of the vial displayed patches of nanowire growth while regions of the substrate near the bottom of the vial showed more uniform coverage of nanowires. This difference in deposition can be explained by the increased precipitation near the top of the vial, which reduced the reactant concentration and their flux to the substrate. By contrast, the batch microreactor's contact heater and horizontal orientation eliminate lateral temperature and concentration gradients along the surface of the substrate, and therefore enabled uniform deposition over the surface of the substrate at early growth nanowire stages.

### 3. Deposition Rate of the ZnO Nanowire Using the CBD Vial Reactor

The ZnO deposition rate was determined by empirically fitting a function (Gompertz function) to the CBD vial reactor's deposition versus time data and calculating its first order derivative. This fit is shown in FIG. 15(a); FIG. 15(b) shows a graph of the deposition rate as a function of time.

In comparison with Example 2, the deposition rate of the batch microreactor reached a maximum of 1.0 μg/mm²/h at 12 min into the reaction while the CBD vial reactor did not reach its maximum deposition rate of 0.60 μg/mm²/h until about 3.5 hours into the reaction. The fast heating rate of the batch microreactor produced a substantially faster deposition rate during the first hour of growth. Additionally, the maximum deposition rate of the batch microreactor was significantly higher and occurred much earlier in the reaction. Comparatively, the maximum deposition rate was about 60% higher. By contrast, the CBD vial reactor had a slower induction period followed by a longer sustained period of a moderate rate of growth.

### 4. Deposition Yield of the ZnO Nanowire Using the CBD Vial Reactor

FIG. 16 shows the ZnO nanowire yield as a function of time for a single substrate in the 27 mL CBD vial reactor when heated at a rate of 2.5° C./min, with error bars based on the errors calculated in FIG. 15(a). Deposition yield of the CBD vial reactor was calculated in the same manner as that disclosed in Example 2. The maximum deposition yield was only 5% after about 6 hours. Further evidence of low yield is shown in FIG. 15(c), wherein 20% of the initial Zn²⁺_{(aq)} remained in the CBD vial reactor after 6 hours; therefore 75% of the initial Zn²⁺_{(aq)} reactant was lost to precipitation or wall deposition. Most of this loss is due to large quantities of precipitation. Additionally, some ZnO deposits were also present on the vial walls. By comparison, after 5 hours in the batch microreactor a similar fraction of the initial Zn²⁺_{(aq)} remains in solution, but the high deposition yield results in only about 40% of the initial reactants being lost to precipitation or wall deposition.

As shown in FIG. 16, the batch microreactor of Example 2 produced a yield that was larger by an order of magnitude than the CBD vial reactor. Given the same starting precursor concentrations in both the batch microreactor and CBD vial reactor, yield normalizes the deposited mass data from FIG. 15(a) by the bath volume. Both the microreactor and CBD vial reactor have approximately the same deposited mass, but the volume of the batch microreactor bath is over 30 times smaller, resulting in a substantially higher yield.

The batch microreactor's high surface-to-volume geometry creates a substantially shorter transport length and allows reactants to diffuse to and deposit on the substrate faster than they can precipitate. Consequently, the batch microreactor produces a significantly higher deposition yield than the CBD vial reactor, where significant precipitation occurs. Additionally, the ability of the batch microreactor to heat the substrate from the back also reduces precipitation in the reaction channel and reduces deposition on the non-substrate reactor walls by creating a temperature gradient across the solution. Calculations using a 1-D heat transfer model show the far reactor wall temperature to be about 10° C. lower than the substrate temperature. This lower temperature results in slower kinetics and less growth on the reactor wall as well as less precipitation in the channel.

### 5. Crystal Quality and Defect Structure of the ZnO Nanowire of the CBD Vial Reactor

Upon comparing the crystal quality and defect structure of the ZnO nanowires grown in the CBD vial reactor and batch microreactor of Example 2 using XRD and Raman spectra imaging, the ZnO nanowires of the batch microreactor were found to be equivalent or superior in quality to those grown in the vial. The nanowires deposited in the CBD vial reactor were equivalent in morphology, crystallinity, and alignment to those grown in the batch microreactor. Additionally, the increased deposition rate in the batch microreactor did not induce strain or comparatively cause any additional defects in the ZnO lattice.

### Example 3

### Continuous Flow Microreactor

In an experimental study, the effect of different flow rates on the growth of ZnO nanowires produced in a microreactor operated under continuous flow was investigated.

The continuous flow microreactor used in the experiment is shown in FIG. 7 and has the same characteristics of the microreactor of Example 2 with the exception that it includes a flow channel for allowing the continuous flow of precursors into and out of the reaction channel and that this flow channel is an oval of length 45 mm and width 18 mm rather than a rectangle. Syringe pumps were used to pump an aqueous precursor solution of 0.025 M zinc nitrate and 0.025 M HMT at room temperature into the reaction chamber via 0.04″ ID PEEK tubing (Upchurch) at flow rates of either 0.72 mL/hr or 2.88 mL/hr over a period of about 4 hours. A dynamic mixer (Gilson 811) with a 67 μl chamber was used to premix the reactants before they entered the reaction channel. The precursor solutions that were employed were not pre-heated. To avoid outgassing of the precursor solutions and bubble formation on the substrate surface, a 20 psi inline back-pressure regulator (Upchurch) was placed in the outlet flow stream. Prior to heating the substrate of the continuous flow microreactor, the reaction channel was filled with an initial charge of precursors equal in concentration to those at the inlet.

The resultant nanowires were imaged using scanning electron microscopy (SEM, Zeiss Supra 50VP). Crystal orientation was determined using X-ray diffraction (XRD, Siemens D500) with Cu Kα radiation. Room temperature photoluminescence spectra were measured using a Renishaw RM2000 spectrometer with a 325 nm HeCd laser excitation source.

FIG. 7 illustrates the continuous flow mode of the continuous flow microreactor wherein the dotted line represents the decreasing [Zn²⁺] and the solid parabolic line represents the velocity profile. In traditional CBD vial reactors and the batch microreactor of Example 2, the bath composition is uniform in space but changes over time throughout the course of the reaction. Conversely, in the continuous flow microreactor, bath composition changes along the length of the reaction channel, but composition at any spatial location is constant throughout the reaction time. This time-independent composition profile enables investigation of the effect of different reaction conditions in space rather than time. This aids in the rapid determination of the effect different process conditions have on a material's morphology and properties. In general, the ZnO nanowire growth rate decreases upon moving further downstream in the reaction channel because precursors are depleted by surface or bulk reactions. The high surface to volume ratio of the microreactor results in the dominant depletion being through surface reactions rather than bulk precipitation due to small mass transport lengths.

### 1. Effect of Flow Rate on Deposition Using a Continuous Flow Microreactor

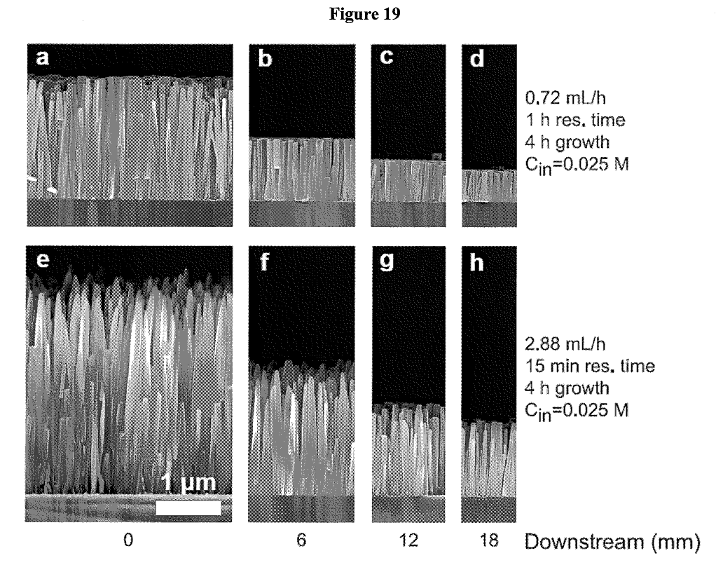

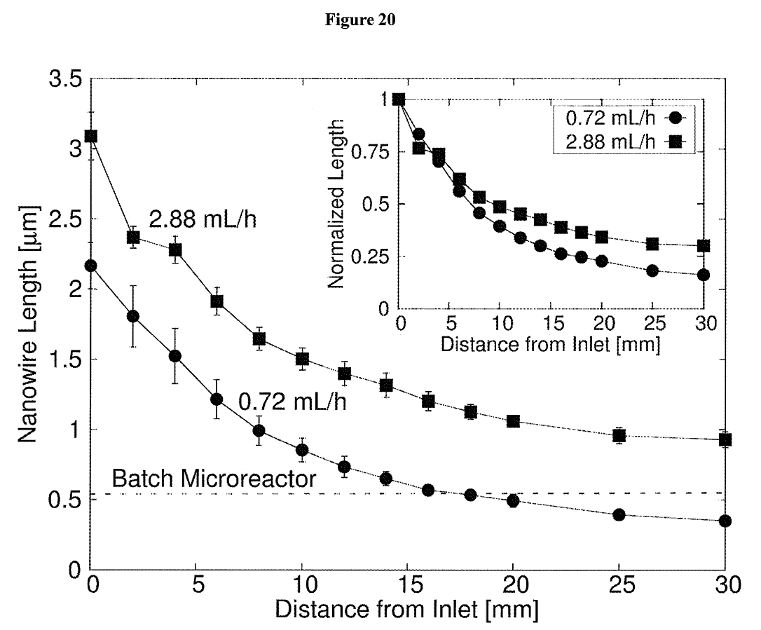

To investigate the change in ZnO deposition rate as a function of position in the reaction channel, micrographs of the nanowires were taken at 0, 6, 12 and 18 mm downstream from the inlet as shown in FIGS. 19(a)-(h). After 4 hours, a continuous flow of a precursor solution at 0.72 mL/hr having an inlet concentration of 0.025 M achieved a maximum length at the inlet of about 1.8 μm which decreased to about 470 nm 18 mm downstream. After 4 hours, a continuous flow of a precursor solution at 2.88 mL/hr having an inlet concentration of 0.025 M produced nanowires having a length of about 3 μm at the inlet and nanowires of about 1.1 μm at a distance of 18 mm from the inlet. For both flow rates nanowire lengths decreased as the distance from the inlet increased. Micrographs were taken at 2 mm increments in the continuous flow microreactor, and the average nanowire length was measured at each point. FIG. 20 shows a graph of nanowire length as a function of position from the inlet for both 0.72 and 2.88 mL/hr flow rates. For purposes of comparison, nanowire length produced by a batch microreactor after 4 h of growth with an initial precursor concentration of 0.025 M is included on the graph. The error bars in FIG. 20 reflect the standard error of the measured length in three samples collected at each of the observed positions. Both flow rates follow the same trend; nanowire length decreased rapidly in the first 10 mm downstream, then more gradually about 10 to about 20 mm downstream. Finally, nanowire length approached a constant value for distances greater than 20 mm from the inlet. At these far distances from the inlet, the nanowires grown at 0.72 mL/hr flow rates were shorter than those grown in the batch microreactor due to the depletion of precursors upstream by surface and bulk reactions (McPeak, K. M.; Baxter, J. B., Microreactor for High-Yield Chemical Bath Deposition of Semiconductor Nanowires: ZnO Nanowire Case Study, Industrial & Engineering Chemistry Research, Feb. 11, 2009). Close inspection of FIG. 20 shows that nanowires grown at 0.72 mL/hr appear to have decreased in length more rapidly than those grown at 2.88 mL/hr. To better compare the relative decrease in nanowire lengths at different flow rates, the average lengths of the nanowires were normalized to their length at the inlet and plotted against position downstream in the inset of FIG. 20. As shown in FIG. 20, faster flow rates result in more uniform length nanowires down the channel.

### 2. Effect of Flow Rate on Nanowire Length Using a Continuous Flow Microreactor

Flow rate also affected the absolute length of the wires in the reactor channel. As shown in FIG. 20, at the inlet the 2.88 mL/hr flow rate resulted in about 50% to about 60% longer wires than the 0.72 mL/hr flow rate. The void fractions of the nanowires for these two flow rates were equivalent; therefore, we can attribute this increase in length at the inlet to a 60% increase in growth rate. Since both flow rates have the same inlet concentration the increase in growth rate with increasing flow rate suggests that ZnO deposition is mass transfer limited. The increased flow rate decreases the mass transfer boundary layer therefore increasing the flux of reactants to the surface.

### 3. Effect of Inlet Concentration on Nanowire Growth Using a Continuous Flow Microreactor

Higher inlet concentrations produced faster growth rates and nanowires having different morphologies. Nanowires formed from precursor solutions having 0.0125 M inlet concentrations were compared to nanowires which used precursor solution having 0.025 M inlet concentrations. In each case, the flow rate was 2.88 mL/hr, and nanowires were examined at 0, 6 and 10 mm downstream from the inlet after 4 hours. The resultant nanowires were hexagonal in cross-section, vertically aligned, and about 80 nm to about 120 nm in diameter at all positions downstream. The tips of the nanowires grown at 0.0125 M concentration were flat or slightly tapered at the inlet while the nanowires grown at 0.025 M concentration were highly tapered, forming pyramid-like structures. Moving further downstream the nanowires reverted to the more commonly observed hexagonal prism structure. The nanowires grown with a 0.0125 M inlet concentration obtain this hexagonal prism morphology within 6 mm of the inlet, while the 0.025 M grown nanowires did not fully lose their pyramid-like structure until about 10 mm downstream. The formation of pyramid-like tips at the end of the nanowires may be attributed to the differences in growth velocities along various directions in the ZnO crystal.

4. Crystal Quality and Defect Structure of Nanowires Grown with a Continuous Flow Microreactor

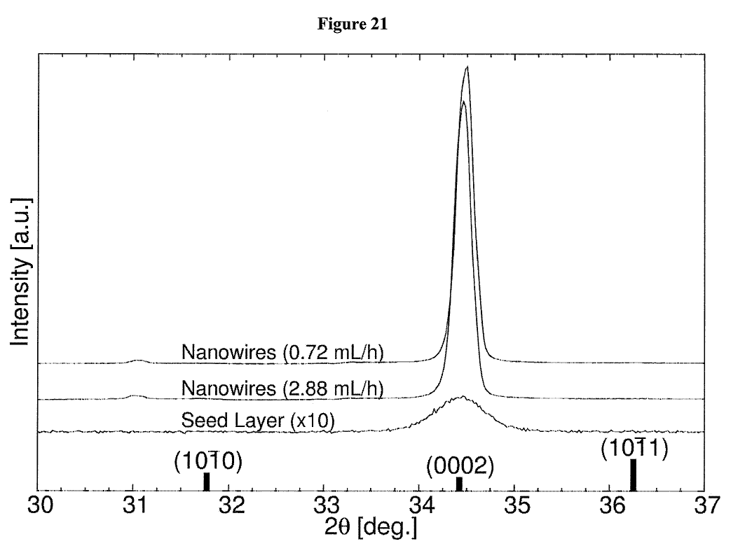

ZnO nanowires grown in the continuous flow microreactor were found to be of excellent quality. FIG. 21 shows normalized 2-theta scans of the nanowires as well as the ZnO seed film along with lines corresponding to peak heights of a reference wurtzite ZnO powder. X-ray diffraction (XRD) of the nanowires grown in the continuous flow microreactor under various growth conditions shows a single major peak that corresponds to the (0002) plane of wurtzite ZnO. Other peaks such as (10 1̅0) and (10 1̅1) that are larger than the (0002) peak in the powder diffraction pattern are not observed in the nanowire diffraction pattern, indicating that the ZnO c-axis is well-aligned perpendicular to the substrate.

While both flow rates resulted in wurtzite ZnO nanowires with good crystallinity, slower flow rates consistently resulted in positive 2-theta shifts for the (0002) plane, as seen in FIG. 21. The (0002) peak for nanowires grown at 0.72 mL/hr flow rate was 34.49° while the nanowires grown at 2.88 mL/hr exhibited an (0002) peak at 34.46°. These 2-theta measurements correspond to an (0002) plane d-spacing of 2.5983 Å and 2.6000 Å respectively. Nanowires grown at slower flow rates exhibited a consistent decrease in their (0002) d-spacing as compared to nanowires grown at faster flow rates. The 2-theta measurement for unstrained bulk ZnO was 34.42°, which corresponds to an (0002) d-spacing of 2.6033 Å (PDF #00-036-1451). The decrease in the (0002) d-spacing observed in samples grown at slower flow rates was due to uniform compressive strain along the c-axis in the nanowires (Li, Y. F.; Yao, B.; Lu, Y. M.; Cong, C. X.; Zhang, Z. Z.; Gai, Y. Q.; Zheng, C. J.; Li, B. H.; Wei, Z. P.; Shen, D. Z.; Fan, X. W.; Xiao, L.; Xu, S. C.; Liu, Y., Characterization of biaxial stress and its effect on optical properties of ZnO thin films, Applied Physics Letters 2007, 91, 021915.). The ZnO seed layer showed only the (0002) diffraction peak at 34.43° which implies that it is free of uniform strain along its c-axis.

5. PL Spectrum of Nanowires Grown with a Continuous Flow Microreactor

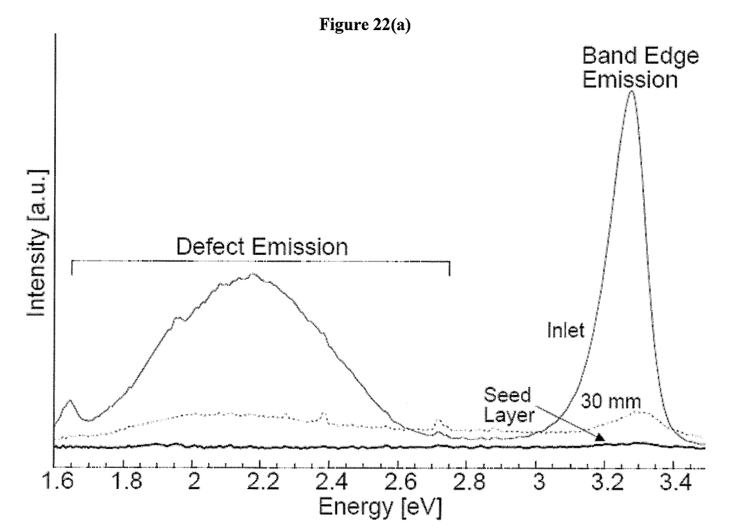

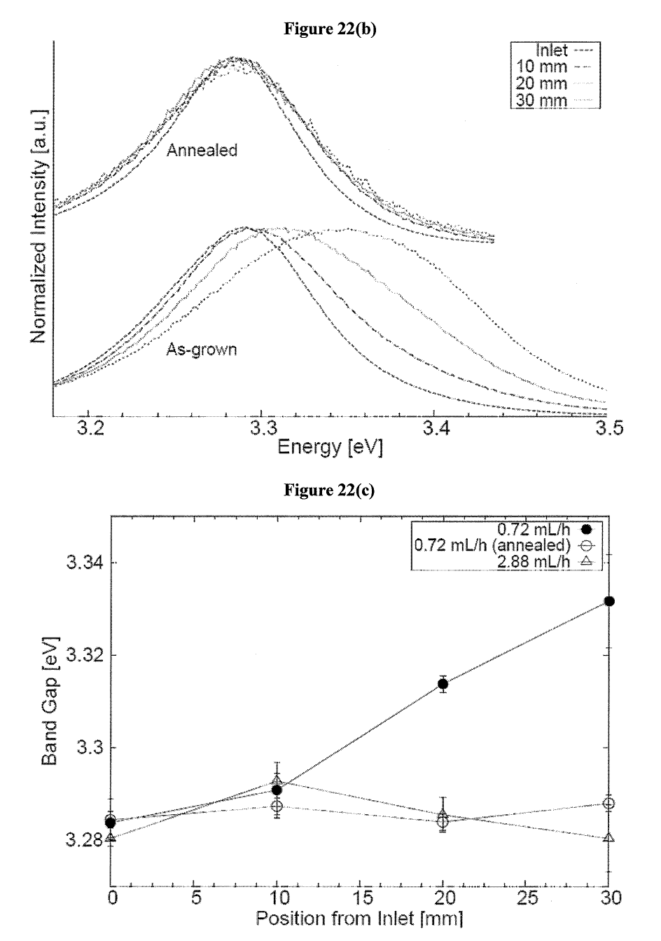

Photoluminescence (PL) measurements of the nanowires show strong band edge emission around 3.28 eV with negligible defect emission from the visible spectrum. PL measurements were taken at 10 mm intervals, with a spot size of 1 μm, between the inlet and outlet points on the substrate to determine if the different reaction conditions in the channel affected the ZnO optical properties. Si wafers were used as substrates for all PL measurement to avoid spurious emission from glass. FIG. 22(a) shows the room temperature PL spectrum for nanowires grown at 0.72 mL/hr with an inlet concentration of 0.025 M zinc nitrate/HMT positioned near the inlet and outlet points as well the PL spectrum for 40 nm thick ZnO seed film. PL measurements taken at the inlet show a sharp band edge emission at 3.28 eV, which corresponds to bulk ZnO's band gap (Ozgur, U.; Alivov, Y. I.; Liu, C.; Teke, A.; Reshchikov, M. A.; Dogan, S.; Avrutin, V.; Cho, S. J.; Morkoc, H., A comprehensive review of ZnO materials and devices, Journal of Applied Physics, 2005, 98.), with a full width at half maximum (FWHM) of 107 meV. PL measurements taken 30 mm downstream from the inlet show a blue shifted band edge emission of about 3.34 eV with a FWHM of 185 meV. Both spectra exhibited some defect emission in the visible range, which indicates point defects. However, ratio of band edge emission to defect emission was equivalent or better in the continuous flow microreactor than in batch vial CBD reactors. Therefore, it can be concluded that the optical quality of the nanowires grown in the continuous flow microreactor is equivalent or better than that of nanowires grown by conventional CBD methods.

The blue shift in the band edge emission observed in the nanowires grown near the outlet of the continuous flow microreactor is attributed to the compressive strain along the c-axis of the nanowires which was observed in XRD scans of samples grown at 0.72 mL/hr flow rates. FIG. 22(b) shows the normalized UV portion of the PL spectra of as-grown and annealed nanowires at various positions down the reaction channel. Annealing relaxes the strain along the c-axis and returns the band gap to its bulk ZnO value at all positions on the substrate (Mandal, S.; Singha, R. K.; Dhar, A.; Ray, S. K., Optical and structural characteristics of ZnO thin films grown by rf magnetron sputtering, Materials Research Bulletin 2008, 43, 244-250). FIG. 22(c) shows band gap as a function of position downstream for nanowires grown formed under a flow rate of about 0.72 mL/hr and about 2.88 mL/hr and for annealed samples grown under a flow rate of about 0.72 mL/hr. The error bars in FIG. 22(c) reflect the standard error of the measured band gap in three samples collected at each of the observed positions. The band gap of the nanowires grown at a 2.88 mL/hr flow rate was consistently measured near the bulk ZnO level of 3.28 eV at all positions on the substrate.

This experiment demonstrates a method for using a continuous flow microreactor as a research tool to enable rapid characterization of different crystal growth conditions on a single substrate. Specifically, the continuous flow microreactor was used to investigate the effect of mass transfer, different inlet concentration and/or different flow rates on the growth rates, growth mechanism, and optical properties of ZnO nanowires as a function of position along the reaction channel. X-ray diffraction and photoluminescence measurements confirm that ZnO nanowires of high crystalline and optical quality have been grown in the continuous flow microreactor. Importantly, variations in morphology and optical properties as a function of position can be correlated to bath composition at that position in the reactor to elucidate the dependence of material properties on growth conditions. This detailed level of analysis is not possible with batch systems, where bath composition changes throughout the course of the experiment. Such studies illustrate the utility of the continuous flow microreactor as a tool to fabricate combinatorial libraries and enable rapid process development using high throughput screening. Conversely, flow rates and flow patterns could be changed as needed to create conditions for uniform growth over relatively large area substrates if that is desired for a given application.

The foregoing examples have been presented for the purpose of illustration and description and are not to be construed as limiting the scope of the invention in any way. The scope of the invention is to be determined from the claims appended hereto.

What is claimed is:

1. A microreactor comprising:
a base defining at least one channel having a bottom, an inlet and an outlet;
a substrate which, when associated with the base, forms a reaction chamber with said at least one channel wherein an average distance from a surface of said substrate facing said channel to said bottom is from 0.1 to 5.0 mm; and
a heating element operatively associated with and capable of transferring heat to said substrate.

2. The microreactor of claim 1, further comprising:
a seal formed between said base and said substrate when said substrate is associated with said base to form a reaction chamber.

3. The microreactor of claim 1, wherein said microreactor comprises a plurality of channels.

4. The microreactor of claim 1, further comprising a pair of electrodes for creating an electric field in said at least one channel.

5. The microreactor of claim 1, further comprising at least one sensor for monitoring a deposition process or a deposition product.

6. The microreactor of claim 5, wherein said sensor is selected from the group consisting of: at least one spectroscopy probe, at least one optical probe, at least one temperature probe, at least one voltammetry probe, or a combination thereof.

7. The microreactor of claim 1, further comprising a device for controlling the velocity of a chemical introduced into said microreactor.

8. The microreactor of claim 1, further comprising a recirculation means for recirculating said chemical to said microreactor.

9. The microreactor of claim 1, having a substrate surface to reactor volume ratio of from about 0.1 to about 10.0 mm⁻¹.

10. The microreactor of claim 1, wherein said average distance is from 0.2 to 2.0 mm.

11. The microreactor of claim 1, wherein said distance is about 0.5 to about 1.5 mm.

12. The microreactor of claim 1, comprising a plurality of reactor inlets located at spaced locations in said channel.

13. The microreactor of claim 1, comprising a plurality of patterned channels to enable patterned deposition on said substrate.

14. The microreactor of claim 1, further comprising a reactant pre-mixing chamber for mixing deposition reactants prior to their introduction into said channel.

15. A method for using a microreactor comprising:
introducing a chemical to said microreactor;
controlling an environmental condition of said microreactor;
depositing said chemical on said substrate, forming a deposition product; and
removing said substrate and said deposition product, wherein during said depositing step, a ratio of a deposition surface on said substrate to a volume of the microreactor is from about 0.1 to about 10.0 mm⁻¹.

16. The method of claim 15, wherein said step of controlling an environmental condition of said microreactor is selected from the group consisting of: adjusting a temperature of said microreactor; adjusting a velocity of said chemical, controlling a duration of a deposition process; adjusting a concentration of said chemical; adjusting a chemical composition; controlling pH or a combination thereof.

17. The method of claim 15, further comprising a step of monitoring a sensor associated with said deposition method and optimizing a parameter of said deposition process based on information obtained by monitoring said sensor.

18. The method of claim 17, wherein said microreactor comprises a plurality of channels and wherein said method further comprising the steps of varying at least one parameter of said deposition process in each channel and determining an effect of said variation on said deposition process.

19. The method of claim 18, further comprising the step of optimizing a parameter of said deposition process based on said determined affect.

20. The method of claim 15, wherein said ratio is from about 0.2 to about 5.0 mm⁻¹.

21. The method of claim 15, wherein said ratio is from about 0.5 to about 1.5 mm⁻¹.

22. The method of claim 18, further comprising the step of continuously introducing and removing said chemical from said reactor so as to create a continuous flow of said chemical through said reactor and forming a combinatorial material library using said reactor.

23. The method of claim 16, further comprising the step of continuously introducing and removing said chemical from said reactor so as to create a continuous flow of said chemical through said reactor and forming a combinatorial material library using said reactor.
